(19) United States
(12) Patent Application Publication
(10) Pub. No.: US 2025/0359373 A1
(43) Pub. Date: Nov. 20, 2025

(54) IMAGE SENSOR AND METHOD FOR FABRICATING THE SAME

(71) Applicant: SAMSUNG ELECTRONICS CO., LTD., Suwon-si (KR)

(72) Inventors: Sunwook KIM, Suwon-si (KR); Jonghoon Park, Suwon-si (KR); Chulsoo Choi, Suwon-si (KR); Junhyeok Jang, Suwon-si (KR)

(73) Assignee: SAMSUNG ELECTRONICS CO., LTD., Suwon-si (KR)

(21) Appl. No.: 19/058,796

(22) Filed: Feb. 20, 2025

(30) Foreign Application Priority Data
May 20, 2024 (KR) 10-2024-0065468

(51) Int. Cl. H10F 39/00

(52) U.S. Cl. CPC H10F 39/8063; H10F 39/024; H10F 39/802; H10F 39/8053

(57) ABSTRACT

An image sensor includes a plurality of pixels, and a color separation lens array provided on the plurality of pixels. The color separation lens array includes a first color separation group adjacent to a center of the first color separation lens array, and a second separation group adjacent to an edge of the first color separation lens array. The width of a first nanopost included in the first color separation group is greater than a width of a second nanopost included in the corresponding second color separation group.

### CROSS-REFERENCE TO RELATED APPLICATIONS

The application is based on and claims benefit of priority under 35 U.S.C. § 119 to Korean Patent Application No. 10-2024-0065468, filed on May 20, 2024, in the Korean Intellectual Property Office, the disclosure of which is incorporated by reference herein in their entireties.

### BACKGROUND

### 1. Field

The disclosure relates generally to image sensors and methods of manufacturing image sensors.

### 2. Description of Related Art

Image sensors are devices that convert optical image signals into electrical signals, and include charge coupled device (CCD) image sensors and complementary metal oxide semiconductor (CMOS) image sensors. Image sensors include a plurality of pixels. Each pixel includes a light-receiving region that receives incident light and converts the incident light into an electrical signal, and a pixel circuit that outputs a pixel signal using charges generated in the light-receiving region.

Recently, demands for image sensors using color separation lens arrays instead of microlenses have been increased to improve photoelectric conversion efficiency. The color separation lens array can improve the photoelectric conversion efficiency of the image sensor without loss of incident light by separating incident light by wavelength region and focusing the incident light into a color filter that transmits the corresponding wavelength region.

However, incident light passing through an infrared cut-off filter exhibits different transmission characteristics depending on the incident angle, which can cause the color separation lens array to have different photoelectric conversion efficiency.

Accordingly, it is necessary to develop image sensors that enhance the light-receiving effect of the color separation lens array located in a region where the incident angle is large. This enhancement can improve the photoelectric conversion efficiency lowered by the infrared cut-off filter in the region where the incident angle is large.

### SUMMARY

One or more aspects of the disclosure provide image sensors with improved photoelectric conversion efficiency.

According to an aspect of the disclosure, there is provided an image sensor including: a pixel layer including a plurality of pixels; and a first color separation lens array provided on the pixel layer, the first color separation lens array including a plurality of first color separation groups, wherein the plurality of first color separation groups include: a first first color separation group adjacent to a center of the first color separation lens array, and a second first color separation group adjacent to an edge of the first color separation lens array, wherein the first first color separation group includes one or more first nanoposts and the second first color separation group includes one or more second nanoposts, and wherein a width of the one or more first nanoposts is greater than a width of the one or more second nanoposts.

According to an aspect of the disclosure, there is provided a method for manufacturing an image sensor including: forming a pixel layer including a plurality of pixels; and forming a first color separation lens array on the pixel layer, the pixel layer including a plurality of first color separation groups, wherein the plurality of first color separation groups include: a first first color separation group adjacent to a center of the first color separation lens array, and a first second color separation group adjacent to an edge of the first color separation lens array, wherein the first first color separation group includes one or more first nanoposts and the second first color separation group includes one or more second nanoposts, and wherein a width of the one or more first nanoposts is greater than a width of the one or more second nanoposts.

According to an aspect of the disclosure, there is provided an image sensor including: a pixel layer; a wiring layer electrically connected to the pixel layer; and an optical element layer configured to focus incident light onto the pixel layer, wherein the optical element layer includes a first color separation lens array including a plurality of first color separation groups, wherein the plurality of first color separation groups include: a first first color separation group adjacent to a center of the first color separation lens array, and a first second color separation group adjacent to an edge of the first color separation lens array, wherein the first first color separation group includes one or more first nanoposts and the second first color separation group includes one or more second nanoposts, and wherein a width of the one or more first nanoposts is greater than a width of the one or more second nanoposts.

Additional aspects will be set forth in part in the description which follows and, in part, will be apparent from the description, or may be learned by practice of one or more example embodiments of the inventive concepts.

### BRIEF DESCRIPTION OF DRAWINGS

The above and other aspects, features, and advantages of some embodiments of the disclosure will be more apparent from the following description taken in conjunction with the accompanying drawings, in which:

FIG. 1 is a block diagram of an image sensor according to one or more example embodiments.

FIG. 2A is a block diagram of a pixel array of FIG. 1.

FIG. 2B is a block diagram of a first pixel group.

FIG. 2C is a block diagram of a second pixel group.

FIG. 3 is an equivalent circuit diagram of the pixel group of FIG. 1.

FIG. 4A is a cross-sectional view corresponding to line A-A′ in FIG. 2B.

FIG. 4B is a cross-sectional view corresponding to line B-B′ in FIG. 2C.

FIGS. 4C, 4D, 4E, 4F, 4G, 4H, and 4I are plan views for explaining the image sensors of FIGS. 4A and 4B.

FIGS. 5, 6, 7, 8, 9, 10, 11, 12, 13, and 14 are cross-sectional views corresponding to A-A′ of FIG. 2B for explaining a method of manufacturing an image sensor according to one or more example embodiments.

FIG. 15A is a cross-sectional view illustrating an image sensor according to one or more example embodiments.

FIGS. 15B and 15C are plan views for explaining the image sensor of FIG. 15A.

FIG. 16 is a cross-sectional view illustrating an image sensor according to one or more example embodiments.

FIG. 17A is a cross-sectional view illustrating an image sensor according to one or more example embodiments.

FIGS. 17B and 17C are plan views for explaining the image sensor of FIG. 17A.

FIG. 18A is a cross-sectional view illustrating an image sensor according to one or more example embodiments.

FIGS. 18B and 18C are plan views for explaining the image sensor of FIG. 18A.

FIG. 19A is a cross-sectional view illustrating an image sensor according to one or more example embodiments.

FIGS. 19B and 19C are plan views for explaining the image sensor of FIG. 19A.

FIG. 20 is a cross-sectional view illustrating an image sensor according to one or more example embodiments.

### DETAILED DESCRIPTION

Hereinafter, one or more example embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are one or more example embodiments, and thus, the disclosure is not limited thereto, and may be realized in various other forms. One or more example embodiments provided in the following description is not excluded from being associated with one or more features of some other example embodiments also provided herein or not provided herein but consistent with the disclosure. It will be also understood that, even if a certain step or operation of manufacturing an apparatus or structure is described later than another step or operation, the step or operation may be performed later than the other step or operation unless the other step or operation is described as being performed after the step or operation.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group comprising A, B, and C”) may be construed as A only, B only, C only, or any combination of two or more of A, B, and C, such as, for instance, ABC, AB, BC, and AC.

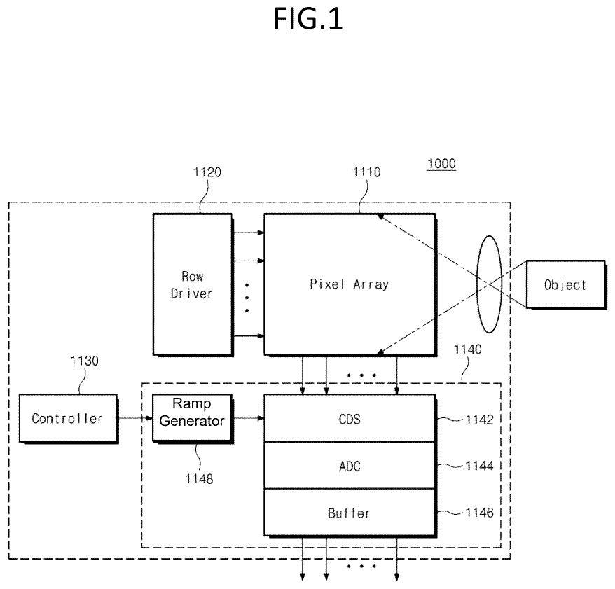

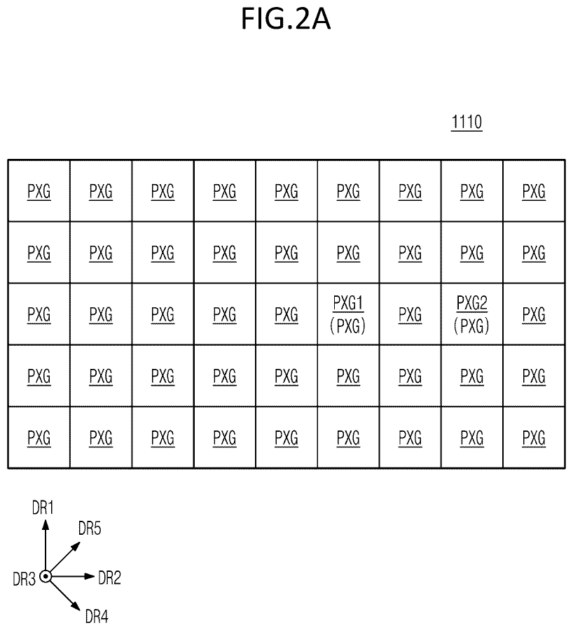

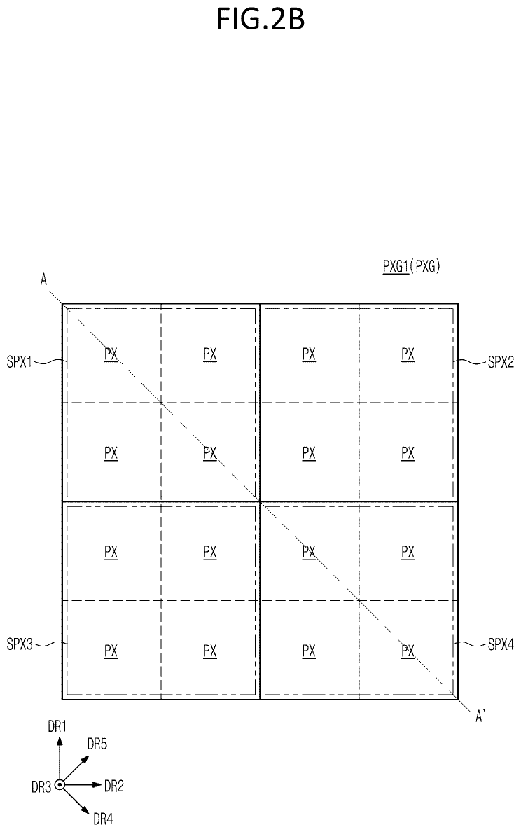

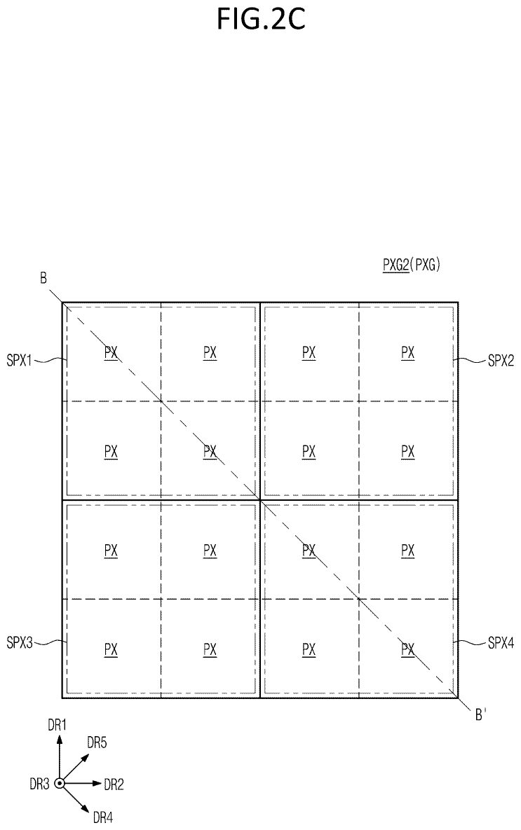

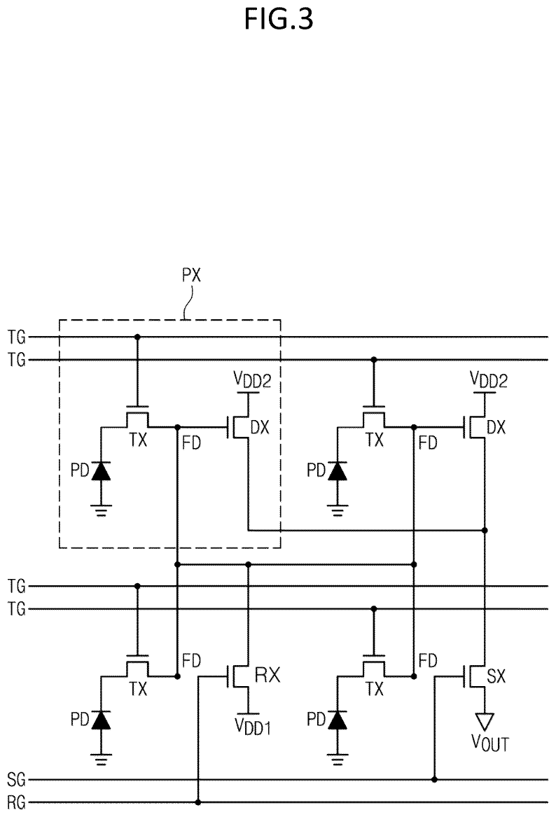

FIG. 1 is a block diagram of an image sensor according to one or more example embodiments. FIG. 2A is a block diagram of a pixel array of FIG. 1. FIG. 2B is a block diagram of a first pixel group. FIG. 2C is a block diagram of a second pixel group. FIG. 3 is an equivalent circuit diagram of the pixel group of FIG. 1.

Referring to FIGS. 1 to 3, an image sensor 1000 may be provided. The image sensor 1000 may be mounted in electronic devices having an image capturing function or light sensing function. For example, the image sensor 1000 may be mount in the electronic devices including, but not limited to, cameras, smartphones, wearable devices, Internet of Things (IoT), tablet PCs (Personal Computers), PDAs (Personal Digital Assistants), PMPs (portable multimedia players), or navigation devices. The image sensor 1000 may be mounted in electronic devices provided as components in various devices (e.g., vehicles, furniture, manufacturing facilities, doors, various measuring devices, etc.).

The image sensor 1000 may include a pixel array 1110, a row driver 1120, a controller 1130, and a pixel signal processor 1140.

Referring to FIGS. 2A to 2C, the pixel array 1110 may include pixel groups PXG arranged along the first direction DR1 and the second direction DR2. The pixel groups PXG may include pixels PX. In one or more example embodiments, each of the pixel groups PXG may include 16 pixels PX arranged in a 4×4 shape. Each of the pixel groups PXG may include a first sub-pixel group SPX1, a second sub-pixel group SPX2, a third sub-pixel group SPX3, and a fourth sub-pixel group SPX4 arranged in a 2×2 array. Each of the first to fourth sub-pixel groups SPX1 to SPX4 may include four pixels PX arranged in a 2×2 array. The first sub-pixel group SPX1 and the second sub-pixel group SPX2 may be arranged along the second direction DR2. The third sub-pixel group SPX3 and the first sub-pixel group SPX1 may be arranged along the first direction DR1. The third sub-pixel group SPX3 and the fourth sub-pixel group SPX4 may be arranged along the second direction DR2. The second sub-pixel group SPX2 and the fourth sub-pixel group SPX4 may be arranged along the first direction DR1. For example, the first sub-pixel group SPX1 and the second sub-pixel group SPX2 may be sequentially arranged along the second direction DR2, The third sub-pixel group SPX3 and the first sub-pixel group SPX1 may be sequentially arranged along the first direction DR1, the third sub-pixel group SPX3 and the fourth sub-pixel group SPX4 may be sequentially arranged along the second direction DR2, and the second sub-pixel group SPX2 and the fourth sub-pixel group SPX4 may be sequentially arranged along the first direction DR1.

The pixel group PXG may include a first pixel group PXG1 provided relatively close to the center of the pixel array 1110 and a second pixel group PXG2 provided relatively far from the center of the pixel array 1110. A chief ray angle (CRA) of the incident light on the second pixel group PXG2 may be greater than the chief ray angle of the incident light on the first pixel group PXG1. For brevity of explanation, the disclosure is described based on the first pixel group PXG1 and the second pixel group PXG2 spaced apart from each other along the second direction DR2.

The pixel array 1110 may be driven by receiving a plurality of driving signals, such as a row selection signal, a reset signal, and a charge transfer signal, from the row driver 1120. The row driver 1120 may provide a plurality of driving signals to the pixel array 1110 for driving the plurality of pixels PX. In one or more example embodiments, the driving signal may be provided in units of rows of the pixel array 1110. Pixels belonging to one row of the pixel array 1110 selected by the driving signals of the row driver 1120 may be simultaneously activated by a signal output from the row driver 1120. The pixels belonging to the selected row may provide output voltages according to absorbed light to the output lines of corresponding columns. In one or more example embodiments, the pixels may provide the output voltages one row at a time. The output voltage may be provided to correlated double sampler 1142.

The pixel signal processor 1140 may include a correlated double sampler (CDS) 1142, an analog-to-digital converter (ADC) 1144, and a buffer 1146. The correlated double sampler 1142 may sample and via hold the output voltages provided by the pixel array 1110. The correlated double sampler 1142 can reduce noise and improve signal-to-noise ratio (SNR). The correlated double sampler 1142 may be configured to remove noise voltage from the output voltage of the pixel. For example, the correlated double sampler 1142 may double sample a specific noise level and a signal level by the output signal and output a difference level corresponding to a difference between the noise level and the signal level. The correlated double sampler 1142 may receive the ramp signal generated by the ramp signal generator 1148, compare the ramp signals, and output a comparison result.

The analog-to-digital converter 1144 may convert an analog signal corresponding to the difference level received from the correlated double sampler 1142 into a digital signal. The buffer 1146 may latch digital signals, and the latched signals may be output to the outside of the image sensor 1100 and transferred to an image processor. The latched signals may be sequentially output to the outside of the image sensor 1100 and transferred to an image processor.

The controller 1130 may control the row driver 1120 to cause the pixel array 1110 to absorb light and accumulate the charge carriers, temporarily store the accumulated charges, and output an electrical signal according to the stored charges to the outside of the pixel array 1110. The controller 1130 may control the pixel signal processor 1140 to measure the output voltage provided by the pixel array 1110.

Each of the plurality of the pixels PX may include a photoelectric conversion element PD, a transfer transistor TX, and a floating diffusion region FD. The photoelectric conversion device PD may generate and accumulate photocharges in proportion to the amount of incident light from the outside. For example, the photoelectric conversion device PD may include a photodiode, a phototransistor, a photogate, a pinned photodiode, or a combination thereof.

The transfer transistor TX may include a transfer gate TG. The transfer gate TG may transfer charge carriers generated by the photoelectric conversion device PD to the floating diffusion region FD. A transfer control voltage provided from the row driver 1120 may be applied to the transfer gate TG. For example, a channel may be formed between the photoelectric conversion device PD and the floating diffusion region FD by the transfer control voltage applied to the transfer gate TG. The charge carriers generated by the photoelectric conversion device PD may be transferred to the floating diffusion region FD along the channel between the photoelectric conversion device PD and the floating diffusion region FD. A drain terminal of the transfer transistor TX may be electrically connected to the floating diffusion region FD, and a source terminal of the transfer transistor TX may be electrically connected to the photoelectric conversion device PD.

The floating diffusion region FD may receive, accumulate, and store charges generated by the photoelectric conversion device PD. The source follower transistor DX may be controlled according to the amount of charge accumulated in the floating diffusion region FD. A gate terminal of the source follower transistor DX may be electrically connected to the floating diffusion region FD. A second power voltage VDD2 may be applied to a drain terminal of the source follower transistor DX. A source terminal of the source follower transistor DX may be electrically connected to a drain terminal of the selection transistor SX. The source follower transistor DX may be a source follower buffer amplifier that outputs a current proportional to the amount of charge accumulated in the floating diffusion region FD.

The reset transistor RX may periodically reset charges accumulated in the floating diffusion region FD. A gate terminal of the reset transistor RX may be electrically connected to a reset signal line RG. A drain terminal of the reset transistor RX may be connected to the floating diffusion region FD, and the source terminal may be connected to the first power voltage VDD1. In one or more example embodiments, the first power voltage VDD1 may be substantially equal to the second power voltage VDD2. In an example case in which the reset transistor RX is turned on, the first power voltage VDD1 connected to the source terminal of the reset transistor RX is transmitted to the floating diffusion region FD. In an example case in which the reset transistor RX is turned on, charges accumulated in the floating diffusion region FD may be discharged and the floating diffusion region FD may be reset. In an example case in which the charge carrier is an electron, the voltage of the floating diffusion region FD may be lowered as electrons accumulate in the floating diffusion region FD. In an example case in which the reset transistor RX is turned on, electrons in the floating diffusion region FD may be discharged to the outside, and the voltage of the floating diffusion region FD may increase to the first power voltage VDD1. As the first power voltage VDD1 is applied to the floating diffusion region FD, the first power voltage VDD1 is applied to the gate terminal of the source follower transistor DX to reset the output of the source follower transistor DX. You can.

The selection transistor SX may select a plurality of pixels PX in each row. According to an embodiment, the selection transistor SX may transfer current generated by the source follower transistor DX included in each of the selected pixels to an output line. A drain terminal, a source terminal, and a gate terminal of the selection transistor SX may be electrically connected to the source terminal, the output line, and the row selection line SG of the source follower transistor DX, respectively. A selection control signal applied from the row selection line SG may be applied to the gate terminal of the selection transistor SX to output a signal generated by the source follower transistor DX to the output line.

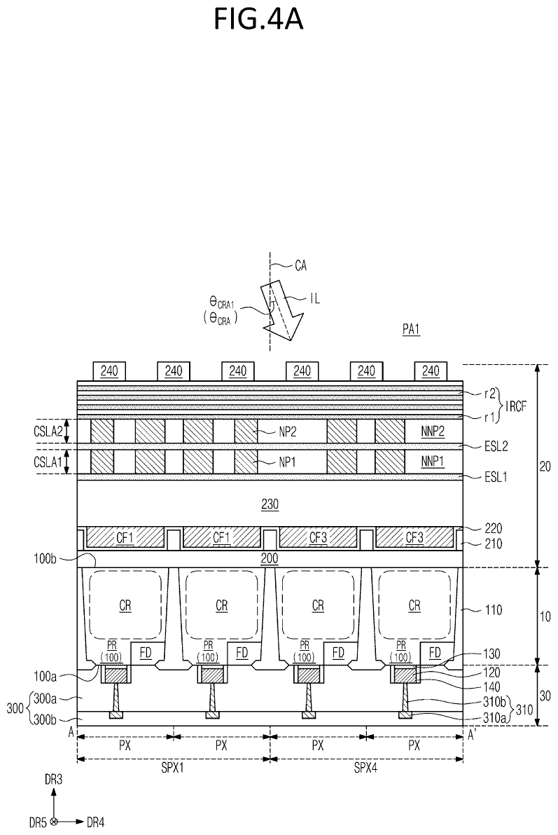

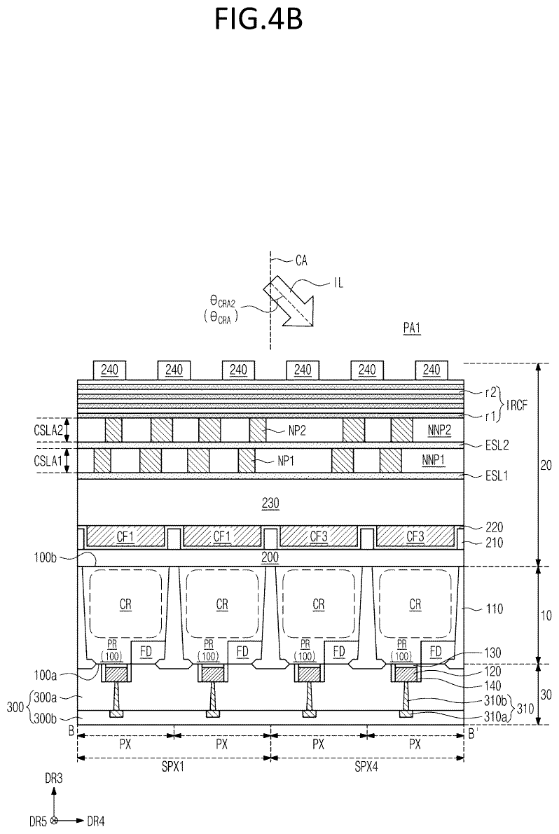

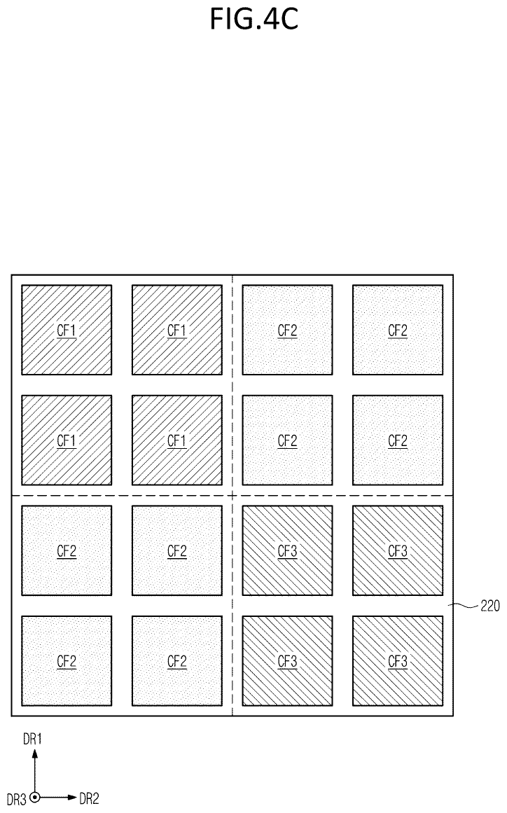

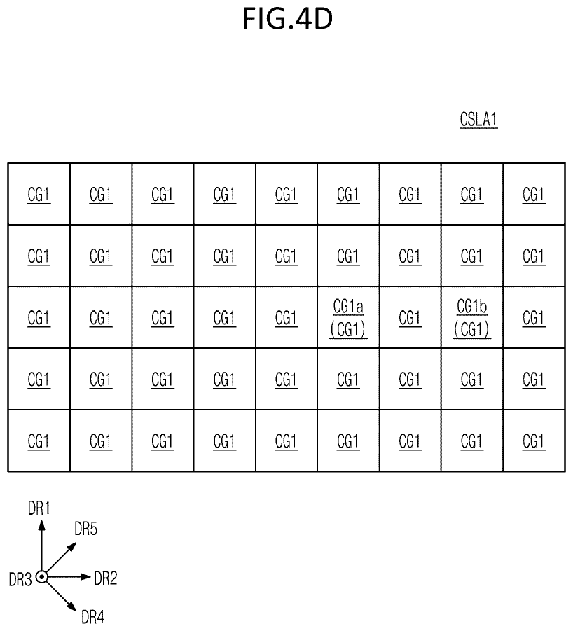

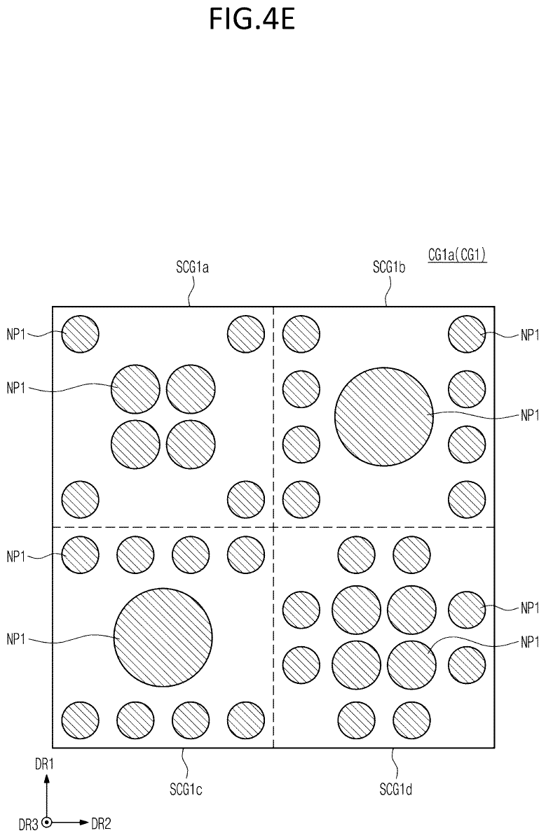

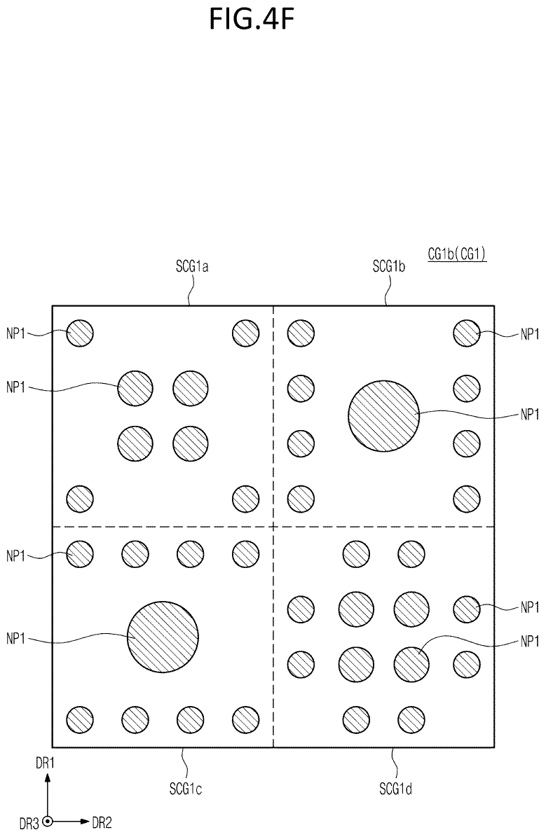

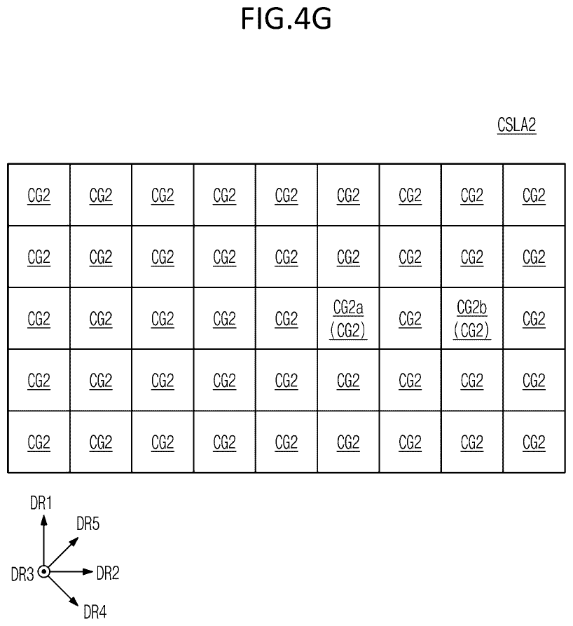

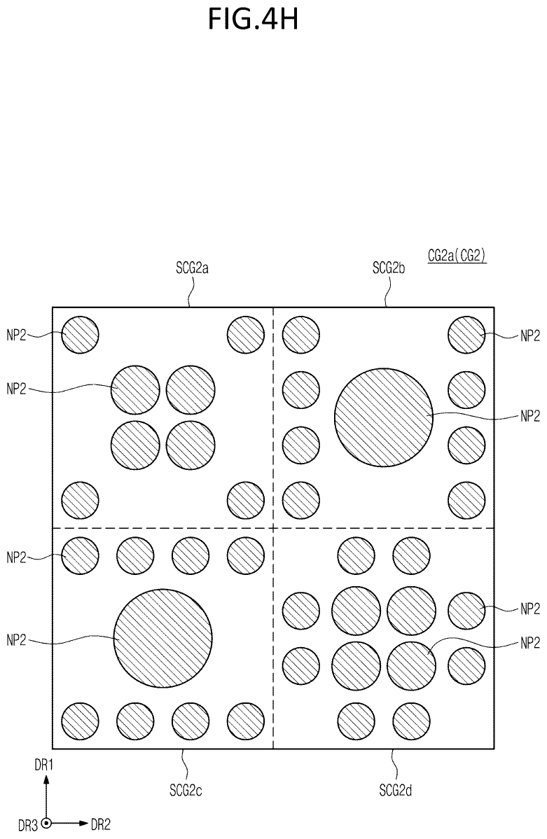

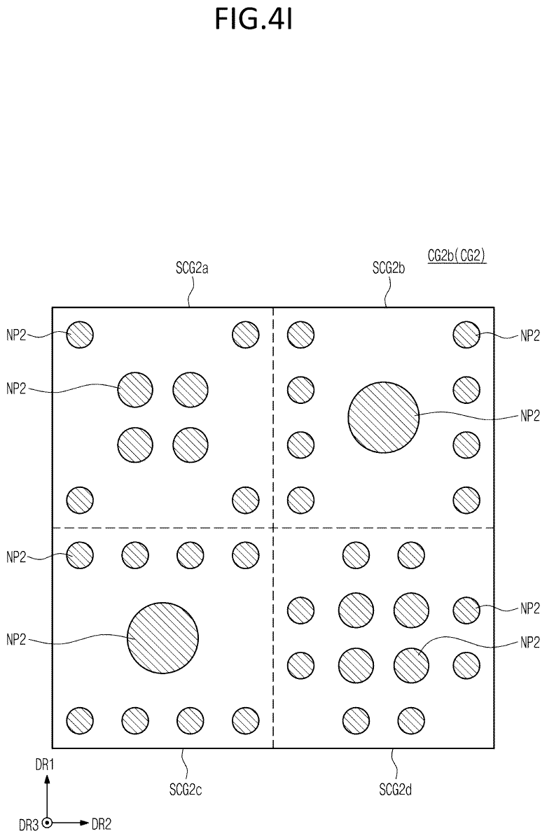

FIG. 4A is a cross-sectional view corresponding to line A-A′ in FIG. 2B. FIG. 4B is a cross-sectional view corresponding to line B-B′ in FIG. 2C. FIGS. 4C, 4D, 4E, 4F, 4G, 4H, and 4I are plan views for explaining the image sensors of FIGS. 4A and 4B.

Referring to FIGS. 4A and 4B, an image sensor PA1 including a device layer 10, an optical element layer 20, and a wiring layer 30 may be provided. According to an embodiment, the device layer 10 may include a pixel layer. The optical element layer 20 and the wiring layer 30 may be spaced apart from each other with the device layer 10 interposed therebetween. The device layer 10 may include pixels PX. For example, the pixel layer of the device layer 10 may include the pixels PX. The device layer 10 may include a substrate region 100. The substrate region 100 may include a semiconductor material. For example, the substrate region 100 may include, but is not limited to, silicon (Si), germanium (Ge), or silicon-germanium (Si—Ge). The substrate region 100 may have a first conductivity type. For example, the first conductivity type may be p-type or n-type. In an example case in which the conductivity type of the substrate region 100 is p-type, the substrate region 100 may be a silicon (Si) region containing a group 3 element or a group 2 element as an impurity. For example, the group 3 element may include, but is not limited to, boron (B), aluminum (Al), gallium (Ga), or indium (In). In an example case in which the conductivity type of the substrate region 100 is n-type, the substrate region 100 may be a silicon (Si) region containing a group 5 element, a group 6 element, or a group 7 element as an impurity. For example, the group 5 element may include, but is not limited to, phosphorus (P), arsenic (As), or antimony (Sb). The substrate region 100 may be an epitaxial layer formed through an epitaxial growth process. The crystal structure of the substrate region 100 may include at least one of a single crystal structure, a polycrystal structure, and an amorphous structure. The substrate region 100 may include a first surface 100a and a second surface 100b facing opposite directions. The first surface 100a and the second surface 100b may extend along the first direction DR1 and the second direction DR2.

The substrate region 100 may include pixel regions PR. The pixel regions PR may refer to the substrate region 100 included in the pixel PX. Each of the pixel regions PR may include photoelectric conversion regions CR. In one or more example embodiments, the photoelectric conversion regions CR may include a photodiode including a first conductivity type region and a second conductivity type region. For example, the photoelectric conversion regions CR may include a pn photodiode. In an example case in which the conductivity type of the substrate region 100 is p-type, the p-type region of the photoelectric conversion regions CR may be the substrate region 100, or a region formed by implanting the group 3 element or the group 2 element as an impurity into the substrate region 100 as an impurity. The n-type region of the photoelectric conversion regions CR may be a region formed by implanting the group 5, 6, or 7 element as an impurity into the substrate region 100. The p-type and the n-type regions may have a potential gradient due to the p-n junction structure. In one or more example embodiments, the photoelectric conversion regions CR include the photodiode. In one or more example embodiments, the photoelectric conversion regions CR may include phototransistors, photogates, or pinned photodiodes.

The device layer 10 may include an isolation layer 110. The isolation layer 110 may define the pixel regions PR. For example, the isolation layer 110 may surround the pixel regions PR. The isolation layer 110 may be extended along the third direction DR3. A width of the isolation layer 110 may become smaller in a direction towards the second surface 100b. However, this is an example. The width of the isolation layer 110 may be determined depending on the manufacturing process and required characteristics of the image sensor PA1. The width of the isolation layer 110 may be the size of the isolation layer 110 along the second direction DR2. In one or more example embodiments, the isolation layer 110 may include a device isolation layer and a pixel isolation layer. The device isolation layer and the pixel isolation layer may be arranged along the third direction DR3. The device isolation layer may be provided adjacent to the first surface 100a. The pixel isolation layer may be provided adjacent to the second surface 100b.

The device isolation layer may define active regions. For example, the device isolation layer may be a shallow trench isolation (STI) layer. From a plan view, the device isolation layer may surround the active regions. Gate electrodes 120 and the floating diffusion regions FD may be provided on the active regions. The device isolation layer may include a silicon-based insulating material. For example, the device isolation layer may include silicon oxide (SiOₓ), silicon nitride (SiNₓ), silicon oxynitride (SiOₓN_{y}), or a combination thereof.

The pixel isolation layer may be configured to optically and electrically separate adjacent pixels from each other. For example, the pixel isolation layer may be a deep trench isolation (DTI) layer. The pixel isolation layer may have a smaller refractive index than that of the substrate region 100. In one or more example embodiments, the pixel isolation layer may prevent, limit or reduce electrical crosstalk, which reduces the signal-to-noise ratio (SNR), by exchanging charge carriers between the adjacent pixel regions PR. For example, the charge carriers may be electrons or holes. For example, the pixel isolation layer may include an electrically conductive material, an electrically insulating material, or a high-k dielectric material. The electrically conductive material may include, but is not limited to, at least one of doped polysilicon, metal, metal silicide, metal nitride, or a metal-containing material. The electrically insulating material may include, but is not limited to, a silicon-based insulating material. The silicon-based insulating material may include, but is not limited to, silicon oxide (SiOₓ), silicon nitride (SiNₓ), and silicon oxynitride (SiOₓN_{y}). The high-k dielectric material may include, but is not limited to, a metal oxide containing at least one metal selected from the group including hafnium (Hf), zirconium (Zr), aluminum (Al), tantalum (Ta), titanium (Ti), yttrium (Y), and lanthanide (La). In one or more example embodiments, a sidewall of the pixel isolation layer may be doped with a highly reflective material. For example, the highly reflective material may include boron (B). In one or more example embodiments, if the pixel isolation layer includes an electrically conductive material, a negative fixed charge layer may be provided between the pixel isolation layer and the substrate region 100. For example, the negative fixed charge layer may include a metal oxide containing at least one metal selected from the group including hafnium (Hf), zirconium (Zr), aluminum (Al), tantalum (Ta), titanium (Ti), yttrium (Y), and lanthanide (La). However, the structure of the pixel isolation layer may be determined as needed. In one or more example embodiments, the pixel isolation layer may be an insulating layer having a single structure.

The device layer 10 may include the floating diffusion regions FD. The floating diffusion regions FD may be provided within the substrate region 100. The floating diffusion regions FD may be provided in each of the pixel regions PR. The floating diffusion regions FD may be provided on one side surface of the gate electrodes 120. The floating diffusion regions FD may be provided adjacent to the first surface 100a. The floating diffusion regions FD may have a second conductivity type. In one or more example embodiments, the floating diffusion regions FD may be formed by implanting second impurities into the substrate region 100. The floating diffusion regions FD may receive and accumulate the charge carriers provided from the pixel regions PR. The floating diffusion regions FD may be included in the drain of the transfer transistor (TX in FIG. 3). The floating diffusion region FD may be electrically connected to the source of the reset transistor (RX in FIG. 3). The floating diffusion region FD may be electrically connected to the source follower gate of the source follower transistor (DX in FIG. 3).

The device layer 10 may include the gate electrodes 120. The gate electrodes 120 may be provided in each of the pixel regions PR. In one or more example embodiments, the gate electrodes 120 may be provided on the first surface 100a. Each of the gate electrodes 120 may function as gate electrodes 120 of the transfer transistors TX different from each other. The gate electrodes 120 may include an electrically conductive material. For example, the gate electrodes 120 may include polysilicon (e.g., doped polysilicon), metal silicide, or metal. The metal may include, but is not limited to, titanium (Ti), tantalum (Ta), tungsten (W), molybdenum (Mo), cobalt (Co), copper (Cu), aluminum (Al), silver (Ag), gold (Au), platinum (Pt), ruthenium (Ru), titanium nitride (TiN), tungsten nitride (WN), niobium nitride (NbN), or a combination thereof.

The device layer 10 may include gate insulating layers 130. The gate insulating layers 130 may be provided between the gate electrodes 120 and the first surface 100a. In one or more example embodiments, the gate insulating layers 130 be extended along a surface of the gate electrodes 120 facing the first surface 100a to electrically separate the gate electrodes 120 and the substrate region 100. For example, the gate insulating layers 130 may include a silicon-based insulating material or a high-k dielectric material (e.g., a metal oxide containing at least one metal selected from the group including hafnium (Hf), zirconium (Zr), aluminum (Al), tantalum (Ta), titanium (Ti), yttrium (Y), and lanthanide (La)). The silicon-based insulating material may include, but is not limited to, silicon oxide (SiOₓ), silicon nitride (SiNₓ), silicon oxynitride (SiOₓN_{y}). The high-k dielectric material may include, but is not limited to, a metal oxide containing at least one metal selected from the group including hafnium (Hf), zirconium (Zr), aluminum (Al), tantalum (Ta), titanium (Ti), yttrium (Y), and lanthanide (La).

The device layer 10 may include gate spacers 140. The gate spacers 140 may be provided on sidewalls of the gate electrodes 120. In one or more example embodiments, the gate spacers 140 may be configured to electrically separate the gate electrodes 120 from other components. For example, the gate spacers 140 may include silicon nitride (SiNₓ), silicon carbide nitride (SiCₓN_{y}), or silicon oxynitride (SiOₓN_{y}). In an example case in which light is incident on the photoelectric conversion regions CR, electron-hole pairs may be generated in the photoelectric conversion regions CR. For example, the electron-hole pairs may be generated in a depletion region formed in a region adjacent to a p-n junction. The stronger the intensity of light incident on the photoelectric conversion regions CR, the more electron-hole pairs may be generated. In an example case in which a reverse bias is applied to the photoelectric conversion regions CR, the charge carriers may be accumulated in the photoelectric conversion regions CR. The charge carriers accumulated in the photoelectric conversion regions CR may be transferred to the floating diffusion regions FD along a channel formed by the voltage applied to the gate electrodes 120. The photoelectric conversion regions CR may be spaced apart from the floating diffusion regions FD.

The optical element layer 20 may include a lower insulating layer 200, a grid 210, a protective layer 220, and a spacer layer 230. The lower insulating layer 200 may be provided on the second surface 100b. For example, the lower insulating layer 200 may be configured to protect the device layer 10. The lower insulating layer 200 may include an electrical insulating material. For example, the lower insulating layer 200 may include, but is not limited to, silicon oxide (SiOₓ), silicon nitride (SiNₓ), silicon oxynitride (SiOₓN_{y}), germanium oxide (GeOₓ), germanium nitride (GeNₓ), germanium oxynitride (GeOₓN_{y}), or a combination thereof. In one or more example embodiments, the lower insulating layer 200 may be configured to reduce or substantially prevent incident light IL from being reflected on the second surface 100b of the substrate region 100. For example, the lower insulating layer 200 may include tantalum (Ta) or tantalum nitride (TaN). In one or more example embodiments, the lower insulating layer 200 may have a single-layer structure or a multi-layer structure.

The grid 210 may be provided on the lower insulating layer 200. The grid 210 may be provided between color filters CF1, CF2, and CF3. The grid 210 may be configured to optically separate the color filters CF1, CF2, and CF3 that are immediately adjacent to each other. The grid 210 may correspond to the isolation layer 110. For example, the grid 210 may be overlapped the isolation layer 110 along the third direction DR3. In one or more example embodiments, the grid 210 may include an electrically conductive material (e.g., metal (e.g., titanium (Ti)) or metal nitride (e.g., titanium nitride (TiN))). In one or more example embodiments, the grid 210 may include a low refractive index material having electrically insulating properties. For example, the low refractive index material may include polymer containing nanoparticles (e.g., silica). In one or more example embodiments, the grid 210 may have a single-layer structure or a multi-layer structure of two or more layers.

The protective layer 220 may be provided between the lower insulating layer 200 and the color filters CF1, CF2, and CF3 and between the grid 210 and the color filters CF1, CF2, and CF3. For example, the protective layer 220 may be extended conformally along surfaces of the grids 210 and the lower insulating layer 200. The protective layer 220 may be configured to protect the grid 210 from the external environment. The protective layer 220 may include a high-k dielectric material having electrically insulating properties. For example, the protective layer 220 may include aluminum oxide (AlOₓ) or hafnium oxide (HfOₓ).

Referring to FIG. 4C, the optical element layer 20 may include first color filters CF1, second color filters CF2, and third color filters CF3. The first to third color filters CF1, CF2, and CF3 may be provided on the lower insulating layer 200. The first to third color filters CF1, CF2, and CF3 may be arranged along a direction parallel to the first surface 100a. The first color filters CF1 may be provided on the first sub-pixel group SPX1. Four first color filters CF1 may be arranged in a 2×2 array on the first sub-pixel group SPX1. For example, the first color filters CF1 may be provided on each of pixels PX of the first sub-pixel group SPX1.

The second color filters CF2 may be provided on the second sub-pixel group SPX2 and the third sub-pixel group SPX3. Four second color filters CF2 may be arranged in a 2×2 array on each of the second sub-pixel group SPX2 and the third sub-pixel group SPX3. For example, the second color filters CF2 may be provided on the pixels PX of the second sub-pixel group SPX2 and the third sub-pixel group SPX3, respectively.

The third color filters CF3 may be provided on the fourth sub-pixel group SPX4. Four third color filters CF3 may be arranged in a 2×2 array on the fourth sub-pixel group SPX4. For example, the third color filters CF3 may be provided on each of the pixels PX of the fourth sub-pixel group SPX4.

Each of the first color filters CF1, the second color filters CF2, and the third color filters CF3 may configured to transmit first wavelength light, second wavelength light, and third wavelength light. The first to third wavelength lights may have different center wavelengths. In one or more example embodiments, each of the first to third wavelength lights may be one of red light, green light, and blue light. In one or more example embodiments, each of the first to third wavelength lights may be one of cyan light, yellow light, and magenta light.

The spacer layer 230 may be extended along a direction parallel to the first surface 100a. The spacer layer 230 may be configured to support a first color separation lens array CSLA1 and a second color separation lens array CSLA2, which will be described later. The spacer layer 230 may be provided on the first to third color filters CF1, CF2, and CF3. A thickness of the spacer layer 230 may be determined according to the focal length f of the incident light TL focused on the pixel regions PR by the first and second color separation lens arrays CLSA1 and CSLA2. The thickness of the spacer layer 230 may be the size between the top surface of the substrate region 100 along the third direction DR3 and the bottom surface of the first and second color separation lens arrays CSLA1 and CSLA2. The focal distance can be determined by the equation as follows.

$$f = \frac{{np}^{2}}{{λ}_{0}} - \frac{{λ}_{0}}{4 n}$$

In this equation, f is the focal length, λ₀ is the center wavelength of the first wavelength light, the center wavelength of the second wavelength light, or the center wavelength of the third wavelength light, n is the refractive index of the spacer layer 230, and p is the width of the pixel regions PR.

The width of the pixel region PR may be a size of the pixel regions PR along the second direction DR2. The thickness of the spacer layer 230 may be less than ½ of the focal length. The spacer layer 230 may be provided to be transparent to visible light. The spacer layer 230 may be provided to have a lower refractive index than that of the first nanoposts NP1 and the second nanoposts NP2. For example, the spacer layer 230 may include at least one of silicon oxide (SiOₓ) and a photo-curable resin (e.g., photoresist and polymethyl methacrylate (PMMA)).

The optical element layer 20 may further include a first etch stop layer ESL1, the first color separation lens array CSLA1, a second etch stop layer ESL2, and the second color separation lens array CLSA2 provided on the spacer layer 230. For example, the optical element layer 20 may include a first etch stop layer ESL1, the first color separation lens array CSLA1, a second etch stop layer ESL2, and the second color separation lens array CLSA2 sequentially stacked on the spacer layer 230. The first etch stop layer ESL1 may be extended along the direction parallel to the first surface 100a. The first etch stop layer ESL1 may be configured to prevent the spacer layer 230 from being damaged during an etching process of forming a first peripheral material layer NNP1. In one or more example embodiments, the first peripheral material layer NNP1 may be formed through the etching process using an etchant or an etchant gas having a high etch selectivity with respect to the first etch stop layer ESL1. For example, the first etch stop layer ESL1 may include at least one of silicon oxide (SiOₓ), aluminum oxide (AlOₓ), hafnium oxide (HfOₓ), titanium oxide (TiOₓ), zirconium oxide (ZrOₓ), silicon nitride (SiNₓ), and silicon nitride (SiOₓN_{y}).

The second etch stop layer ESL2 may be extended along the direction parallel to the first surface 100a. The second etch stop layer ESL2 may be configured to prevent the first color separation lens array CSLA1 from being damaged during an etching process of forming a second peripheral material layer NNP2. In one or more example embodiments, the second peripheral material layer NNP2 may be formed through the etching process using an etchant or an etchant gas having a high etch selectivity with respect to the second etch stop layer ESL2. For example, the second etch stop layer ESL2 may include at least one of silicon oxide (SiOₓ), aluminum oxide (AlOₓ), hafnium oxide (HfOₓ), titanium oxide (TiOₓ), zirconium oxide (ZrOₓ), silicon nitride (SiNₓ), and silicon nitride (SiOₓN_{y}).

Referring to FIGS. 4A to 4F, the first color separation lens array CSLA1 may include first nanoposts NP1 and the first peripheral material layer NNP1 filling between the first nanoposts NP1. From a plan view, in one or more example embodiments, the first nanoposts NP1 are circular. The shape of the first nanoposts NP1 may be determined as needed. For example, the shape of the first nanoposts NP1 may be at least one of a circular ring, an oval, an oval ring, a square, a square ring, a rectangle, a rectangular ring, a cross, and a cross-shaped ring.

A thickness of the first nanoposts NP1 may be substantially the same as a thickness of the first peripheral material layer NNP1. The thickness of the first nanoposts NP1 may be the size of the first nanoposts NP1 along the third direction DR3. The thickness of the first peripheral material layer NNP1 may be the size of the first peripheral material layer NNP1 along the third direction DR3. A refractive index of the first nanoposts NP1 may be higher than a refractive index of the first peripheral material layer NNP1. For example, the first nanoposts NP1 may include at least one of silicon (e.g., single-crystalline silicon (c-Si), polycrystalline silicon (p-Si), and amorphous silicon (a-Si)), silicon nitride (SiNₓ), group 3 compound semiconductors, group 4 compound semiconductors or group 5 compound semiconductors. The groups 3 to 5 compound semiconductors may include, but is not limited to gallium arsenide (GaAs), gallium phosphide (GaP), and gallium nitride (GaN)), silicon carbide (SiC), and titanium oxide (TiOₓ). For example, the first peripheral material layer NNP1 may include an electrical insulating material (e.g., silicon oxide (SiOₓ) or air).

The first color separation lens array CSLA1 may include first color separation groups CG1 arranged along the first direction DR1 and the second direction DR2. Each of the first color separation groups CG1 may include a 1a sub-color separation group SCG1a, a 1b sub-color separation group SCG1b, a 1c sub-color separation group SCG1c, and a 1d sub-color separation group SCG1d arranged in a 2×2 array. The 1a sub-color separation group SCG1a and the 1b sub-color separation group SCG1b may be arranged along the second direction DR2. The 1c sub-color separation group SCG1c and the 1a sub-color separation group SCG1a may be arranged along the first direction DR1. The 1c sub-color separation group SCG1c and the 1d sub-color separation group SCG1d may be arranged along the second direction DR2. The 1b sub-color separation group SCG1b and the 1d sub-color separation group SCG1d may be arranged along the second direction DR2. For example, the 1a sub-color separation group SCG1a and the 1b sub-color separation group SCG1b may be sequentially arranged along the second direction DR2, the 1c sub-color separation group SCG1c and the 1a sub-color separation group SCG1a may be sequentially arranged along the first direction DR1, the 1c sub-color separation group SCG1c and the 1d sub-color separation group SCG1d may be sequentially arranged along the second direction DR2, and the 1b sub-color separation group SCG1b and the 1d sub-color separation group SCG1d may be sequentially arranged along the second direction DR1. The first color separation groups CG1 may include the first nanoposts NP1 having substantially the same arrangement pattern. In one or more example embodiments, within each of the 1a to the 1d sub-color separation groups SCG1a to SCG1d, the first nanoposts NP1 may include at least one central nanopost and at least one peripheral nanopost provided around the at least one central nanopost. The 1a sub-color separation groups SCG1a within the first color separation groups CG1 different from each other may include the first nanoposts NP1 arranged in substantially the same pattern. The 1b sub-color separation groups SCG1b within the first color separation groups CG1 different from each other may include the first nanoposts NP1 arranged in substantially the same pattern. The 1c sub-color separation groups SCG1c within the first color separation groups CG1 different from each other may include the first nanoposts NP1 arranged in substantially the same pattern. The 1d sub-color separation groups SCG1d in the first color separation groups CG1 different from each other may include the first nanoposts NP1 arranged in substantially the same pattern. Each of the first color separation groups CG1 different from each other may include the corresponding first nanoposts NP1. For example, the first nanoposts NP1 corresponding to each other may be provided at the same positions within the first color separation groups CG1 different from each other.

The first color separation groups CG1 may include a 1a color separation group CG1a provided relatively adjacent to the center of the first color separation lens array CSLA1, and a 1b color separation group CG1b provided far from the center of the first color separation lens array CSLA1. The chief ray angle of the light incident on the 1b color separation group CG1b may be greater than the chief ray angle of the light incident on the 1a color separation group CG1a. For brevity of explanation, the disclosure is described based on the 1a color separation group CG1a and the 1b color separation group CG1b spaced apart from each other along the second direction DR2. The 1a color separation group CG1a may be provided on the first pixel group PXG1. The 1b color separation group CG1b may be provided on the second pixel group PXG2.

The first nanoposts NP1 in the 1b color separation group CG1b may have a smaller width than that of the first nanoposts NP1 in the 1a color separation group CG1a. For example, each of the 1a to the 1d sub-color separation groups SCG1a to SCG1d in the 1b color separation group CG1b may have the first nanoposts NP1 having a width smaller than that of the 1a to the 1d sub-color separation groups SCG1a to SCG1d in the 1a color separation group CG1a. The size difference between the widths of the first nanoposts NP1 in the 1a color separation group CG1a and the widths of the first nanoposts NP1 in the 1b color separation group CG1b may be determined according to the chief ray angle of the incident light on the 1a color separation group CG1a and the 1b color separation group CG1b. For example, as the chief ray angle of incident light on the first color separation groups CG1 is increased by 1 degree, the width of the first nanoposts NP1 may be decreased by 0.227 percent (%).

The second color separation lens array CSLA2 may include the second nanoposts NP2 and the second peripheral material layer NNP2 filling between the second nanoposts NP2. From a plan view, in one or more example embodiments, a shape of the second nanoposts NP2 are a circular shape. The shape of the second nanoposts NP2 may be determined as needed. For example, the shape of the second nanoposts NP2 may be at least one of a circular ring, an oval, an oval ring, a square, a square ring, a rectangle, a rectangular ring, a cross, and a cross-shaped ring shape.

A thickness of the second nanoposts NP2 may be substantially the same as a thickness of the second peripheral material layer NNP2. The thickness of the second nanoposts NP2 may be the size of the second nanoposts NP2 along the third direction DR3. The thickness of the second peripheral material layer NNP2 may be the size of the second peripheral material layer NNP2 along the third direction DR3. The refractive index of the second nanoposts NP2 may be higher than that of the second peripheral material layer NNP2. For example, the second nanoposts NP2 may include at least one of silicon (e.g., single-crystalline silicon (c-Si), polycrystalline silicon (p-Si), and amorphous silicon (a-Si)), silicon nitride (SiNₓ), or group 3-5 compound semiconductors (e.g., gallium arsenide (GaAs), gallium phosphide (GaP), and gallium nitride (GaN)), silicon carbide (SiC), and titanium oxide (TiOₓ). For example, the second peripheral material layer NNP2 may include an electrical insulating material (e.g., silicon oxide (SiOₓ) or air).

The second color separation lens array CSLA2 may include second color separation groups CG2 arranged along the first direction DR1 and the second direction DR2. Each of the second color separation groups CG2 may include a 2a sub-color separation group SCG2a, a 2b sub-color separation group SCG2b, a 2c sub-color separation group SCG2c, and a 2d sub-color separation group SCG2d arranged in a 2×2 array. The 2a sub-color separation group SCG2a and the 2b sub-color separation group SCG2b may be sequentially arranged along the second direction DR2. The 2c sub-color separation group SCG2c and the 2a sub-color separation group SCG2a may be sequentially arranged along the first direction DR1. The 2c sub-color separation group SCG2c and the 2d sub-color separation group SCG2d may be sequentially arranged along the second direction DR2. The 2b sub-color separation group SCG2b and the 2d sub-color separation group SCG2d may be arranged along the second direction DR1. For example, the 2a sub-color separation group SCG2a and the 2b sub-color separation group SCG2b may be sequentially arranged along the second direction DR2, the 2c sub-color separation group SCG2c and the 2a sub-color separation group SCG2a may be sequentially arranged along the first direction DR1, the 2c sub-color separation group SCG2c and the 2d sub-color separation group SCG2d may be sequentially arranged along the second direction DR2, and the 2b sub-color separation group SCG2b and the 2d sub-color separation group SCG2d may be sequentially arranged along the second direction DR1. The second color separation groups CG2 may include the second nanoposts NP2 having substantially the same arrangement pattern. The 2a sub-color separation groups SCG2a within the second color separation groups CG2 different from each other may include the second nanoposts NP2 arranged in substantially the same pattern. The 2b sub-color separation groups SCG2b within the second color separation groups CG2 different from each other may include the second nanoposts NP2 arranged in substantially the same pattern. The 2c sub-color separation groups SCG2c within the second color separation groups CG2 different from each other may include the second nanoposts NP2 arranged in substantially the same pattern. The 2d sub-color separation groups SCG2d within the second color separation groups CG2 different from each other may include the second nanoposts NP2 arranged in substantially the same pattern. Each of the second color separation groups CG2 different from each other may include the corresponding second nanoposts NP2. For example, the second nanoposts NP2 corresponding to each other may be provided at the same positions within the second color separation groups CG2 different from each other.

The second color separation groups CG2 may include a 2a color separation group CG2a provided relatively adjacent to the center of the second color separation lens array CSLA2, and a 2b color separation group CG2b provided far from the center of the second color separation lens array CSLA2. The chief ray angle of the light incident on the 2b color separation group CG2b may be greater than the chief ray angle of the light incident on the 2a color separation group CG2a. For brevity of explanation, the disclosure is described based on the 2a color separation group CG2a and the 2b color separation group CG2b spaced apart from each other along the second direction DR2. The 2a color separation group CG2a may be provided on the first pixel group PXG1. The 2b color separation group CG2b may be provided on the second pixel group PXG2.

The second nanoposts NP2 in the 2b color separation group CG2b may have a smaller width than that of the second nanoposts NP2 in the 2a color separation group CG2a. For example, the 2a to 2d sub-color separation groups SCG2a to SCG2d in the 2b color separation group CG2b may have the second nanoposts NP2 with smaller width than that of the 2a to 2d sub-color separation groups SCG2a to SCG2d in the 2a color separation group CG2a. The size difference between the widths of the second nanoposts NP2 in the 2a color separation group CG2a and the widths of the second nanoposts NP2 in the 2b color separation group CG2b may be determined according to the chief ray angle of incident light on the 2a color separation group CG2a and the 2b color separation group CG2b. For example, as the chief ray angle of incident light on the second color separation groups CG2 is increased by 1 degree, the width of the second nanoposts NP2 may be decreased by 0.227 percent (%).

The first and second color separation lens arrays CSLA1 and CSLA2 may be substantially same each other. The first nanoposts NP1 of the first color separation lens array CSLA1 and the second nanoposts NP2 of the second color separation lens array CSLA2 may have substantially the same array pattern and width each other. In one or more example embodiments, the first nanoposts NP1 of the first color separation lens array CSLA1 and the second nanoposts NP2 of the second color separation lens array CSLA2 may overlap along the third direction DR3. In one or more example embodiments, the first nanoposts NP1 of the first color separation lens array CSLA1 and the second nanoposts NP2 of the second color separation lens array CSLA2 may be spaced apart from each other. For example, the first nanoposts NP1 and the second nanoposts NP2 located in a region close to the center of the first and second color separation lens arrays CSLA1 and CSLA2 may be configured to overlap each other along the third direction DR3, but the first nanoposts NP1 and the second nanoposts NP2 located in a region far from the center of the first and second color separation lens arrays CSLA1 and CSLA2 may be configured not to overlap each other along the third direction DR3.

The first nanoposts NP1 of the first color separation group CG1 and the second nanoposts NP2 of the second color separation group CG2 may have substantially the same array pattern and different widths each other. For example, the first nanoposts NP1 and the second nanoposts NP2 may overlap along the third direction DR3. The first and second color separation lens arrays CSLA1 and CSLA2 may be configured to separate and focus incident light IL passing through the first and second color separation lens arrays CSLA1 and CSLA2 into the first wavelength light, the second wavelength light, and the third wavelength light. For example, the first and second color separation lens arrays CSLA1 and CSLA2 may be configured to focus the first wavelength light into the first sub-pixel group SPX1. For example, the first and second color separation lens arrays CSLA1 and CSLA2 may be configured to focus the second wavelength light into the second and third sub-pixel groups SPX2 and SPX3. For example, the first and second color separation lens arrays CSLA1 and CSLA2 may be configured to focus the third wavelength light into the fourth sub-pixel group SPX4.

Referring to FIGS. 4A and 4B, the optical element layer 20 may further include an infrared cut-off filter IRCF. The infrared cut-off filter IRCF may be provided on the first and second color separation lens arrays CSLA1 and CSLA2. The infrared cut-off filter IRCF may be provided along the direction parallel to the first surface 100a. The infrared cut-off filter IRCF may be provided to block a fraction of the incident light IL. For example, the fraction of the incident light IL may be incident light IL having wavelength band in the infrared range. For example, the cut-off filter IRCF may be configured to block light having infrared wavelength. The infrared cut-off filter IRCF may include a first refractive layer r1 and a second refractive layer r2. The infrared cut-off filter IRCF may include at least one of the first and second refractive layers r1 and r2. For example, the infrared cut-off filter IRCF may be configured so that the first and second refractive layers r1 and r2 intersect each other. Although the infrared cut-off filter IRCF is illustrated as including four first refractive layer r1 and four second refractive layer r2, this is an example. In one or more example embodiments, the infrared cut-off filter IRCF may include fewer or more than eight first and second refractive layers r1 and r2, respectively. A refractive index of the first refractive layer r1 may be provided to be smaller than a refractive index of the second refractive layer r2. For example, the first refractive layer r1 may include silicon oxide (SiOₓ). For example, the second refractive layer r2 may include titanium oxide (TiOₓ) or tantalum oxide (TaOₓ).

The optical element layer 20 may further include anti-reflective patterns 240. The anti-reflective patterns 240 may be provided on the infrared cut-off filter IRCF. The anti-reflective patterns 240 may be provided along the direction parallel to the first surface 100a. The anti-reflective patterns 240 may be spaced apart from each other. The anti-reflective patterns 240 may be provided to prevent the incident light IL from being reflected on top surfaces of the first and second color separation lens arrays CSLA1 and CSLA2. The anti-reflective patterns 240 and nanoposts may have different refractive index. For example, the anti-reflective patterns 240 may include at least one of silicon oxide (SiOₓ) and silicon nitride (SiNₓ).

The wiring layer 30 may include wire insulating layers 300 and wires 310. In one or more example embodiments, the wire insulating layer 300 may include two insulating layers (i.e., a first wire insulating layer 300a and a second wire insulating layer 300b). In other one or more example embodiments, the wire insulating layer 300 may include three or more insulating layers. The first and second wire insulating layers 300a and 300b may include an electrically insulating material. For example, the first and second wire insulating layers 300a and 300b are may include silicon oxide (SiOₓ), silicon nitride (SiNₓ), silicon oxynitride (SiOₓN_{y}), germanium oxide (GeOₓ), germanium nitride (GeNₓ), germanium oxynitride (GeOₓN_{y}), or a combination thereof.

The wires 310 may be provided in the first and second wire insulating layers 300a and 300b. The wires 310 may include horizontal wires 310a and vertical wires 310b. The horizontal wires 310a may be extended along the direction parallel to the first surface 100a. The vertical wires 310b may be extended along a direction perpendicular to the first surface 100a (e.g., the third direction DR3). The illustrated wires 310 are examples. The shape and number of wires 310 may be appropriately determined as needed. The wires 310 may output electrical signals generated in the pixel regions PR to the outside. For example, the wires 310 may be provided between the floating diffusion regions FD and other electrical components to provide electrical connections between the floating diffusion regions FD and other electrical components. The wires 310 may include an electrically conductive material (e.g., metal). For example, the wires 310 may include at least one of titanium (Ti), tantalum (Ta), tungsten (W), molybdenum (Mo), cobalt (Co), copper (Cu), aluminum (Al), silver (Ag), gold (Au), platinum (Pt), ruthenium (Ru), titanium nitride (TiN), tungsten nitride (WN), and niobium nitride (NbN). The wires 310 may be electrically connected to at least one of a transmission gate, a source follower gate, a reset gate, and a selection gate. For example, the wires 310 may be configured to apply the power supply voltage VDD to the drain of the reset transistor RX or the drain of the source follower transistor DX.

According to one or more example embodiments of the disclosure, the incident light IL may be separated by the first and the second color separation lens arrays CSLA1 and CSLA2 into the first to the third wavelength lights and focused on the first to the fourth sub-pixel groups SPX1 to SPX4. The first and the second nanoposts NP1 and NP2 may contribute to generate current in the image sensor PA1 by focusing the incident light IL on required pixel regions PR. Accordingly, the image sensor PA1 with improved photoelectric conversion efficiency can be provided.

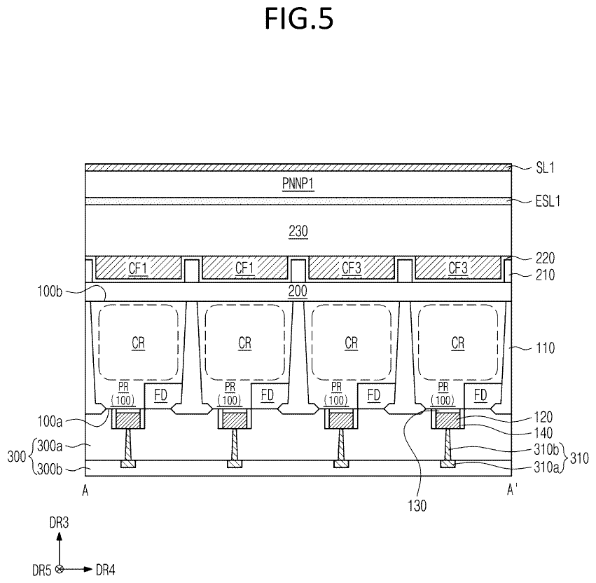

FIGS. 5, 6, 7, 8, 9, 10, 11, 12, 13, and 14 are cross-sectional views corresponding to A-A′ of FIG. 2B for explaining a method of manufacturing an image sensor according to one or more example embodiments. For brevity of explanation, content substantially the same as that described with reference to FIGS. 4A to 4I may not be described.

Referring to FIG. 5, according to an embodiment, the method may include forming a first etch stop layer ESL1 on a spacer layer 230. The first etch stop layer ESL1 may be provided along a direction parallel to a first surface 100a (e.g., in a first direction DR1, a second direction DR2, or a direction combined with the first direction DR1 and the second direction DR2). The first etch stop layer ESL1 may be configured to prevent the spacer layer 230 from being damaged when the first preliminary peripheral material layer PNNP1, which will be described later, is etched. The first etch stop layer ESL1 may not be etched with the material used to etch the first preliminary peripheral material layer PNNP1. For example, the first etch stop layer ESL1 may include at least one of silicon oxide (SiOₓ), aluminum oxide (AlOₓ), hafnium oxide (HfOₓ), titanium oxide (TiOₓ), zirconium oxide (ZrOₓ), silicon nitride (SiNₓ), and silicon nitride (SiOₓN_{y}). For example, depositing the first etch stop layer ESL1 may be performed using physical vapor deposition (PVD) process, chemical vapor deposition (CVD) process, and atomic layer deposition (ALD) process. However, the disclosure is not limited thereto, and as such, according to another embodiment, another process may be used to form the first etch stop layer ESL1.

According to an embodiment, the method may include forming a first preliminary peripheral material layer PNNP1 on the first etch stop layer ESL1. The first preliminary peripheral material layer PNNP1 may be provided along the direction parallel to the first surface 100a. The first preliminary peripheral material layer PNNP1 and a first preliminary nanopost layer PNP1, which will be described later may have different refractive index. The first preliminary peripheral material layer PNNP1 may include a material having a low refractive index. For example, the first preliminary peripheral material layer PNNP1 may include an electrically insulating material (e.g., silicon oxide (SiOₓ) and a photocurable resin (e.g., at least one of photoresist or polymethyl methacrylate). For example, depositing the first preliminary peripheral material layer PNNP1 may be performed using physical vapor deposition (PVD) process, chemical vapor deposition (CVD) process, and atomic layer deposition (ALD) process.

According to an embodiment, the method may include forming a first sacrificial layer SL1 on the first preliminary peripheral material layer PNNP1. The first sacrificial layer SL1 may be provided along the direction parallel to the first surface 100a. The first sacrificial layer SL1 may include an organic material. For example, the first sacrificial layer SL1 may include photoresist. The first sacrificial layer SL1 may be formed through a coating process. For example, the coating process may include spin-coating method, spray-coating method, dip-coating method, inkjet printing method, or slot die coating.

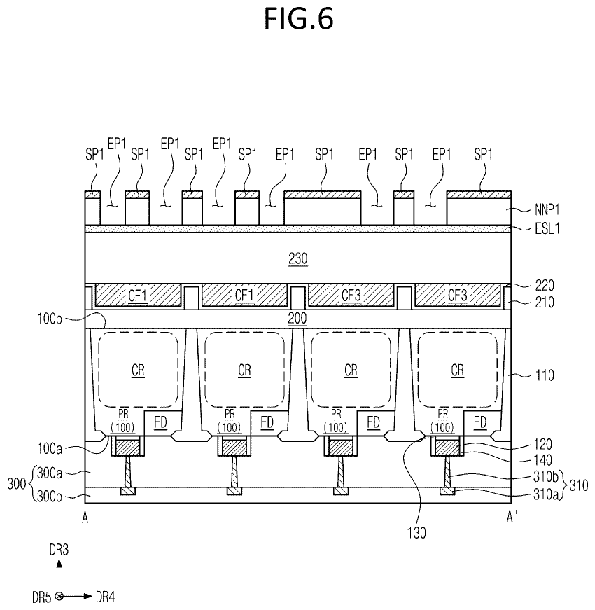

Referring to FIG. 6, according to an embodiment, the method may include forming first sacrificial patterns SP1 by patterning the first sacrificial layer SL1. For example, the first sacrificial layer SL1 may be patterned to form the first sacrificial patterns SP1. According to an embodiment, forming the first sacrificial patterns SP1 may include an exposure process of irradiating light to a required region of the first sacrificial layer SL1 and a development process of removing either an exposed portion or a unexposed portion. The first sacrificial patterns SP1 may be spaced apart from each other. The first preliminary peripheral material layer PNNP1 may be exposed between the first sacrificial patterns SPL.

According to an embodiment, the method may include forming a first engraved patterns EP1 by etching the first preliminary peripheral material layer PNNP1. For example, the first preliminary peripheral material layer PNNP1 may be etched to form the first engraved patterns EP1. Forming the first engraved patterns EP1 may include an etching process using the first sacrificial patterns SP1 provided on the first preliminary peripheral material layer PNNP1. Forming the first engraved patterns EP1 may be performed until the first etch stop layer ESL1 is exposed. When forming the first engraved patterns EP1, the first preliminary peripheral material layer PNNP1 may be formed as a first peripheral material layer NNP1. The first sacrificial patterns SP1 may be removed during or after the etching process. For example, the etching process may be performed using a dry etching process or a wet etching process.

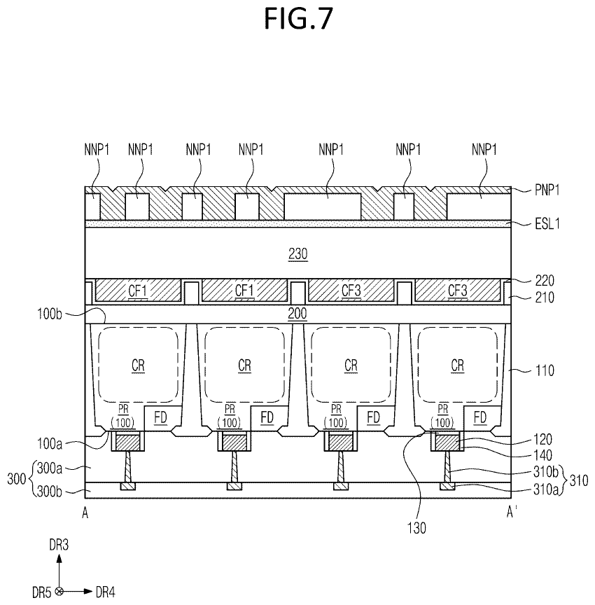

Referring to FIG. 7, according to an embodiment, the method may include forming a first preliminary nanopost layer PNP1 by filling the first engraved pattern EP1. For example, a first preliminary nanopost layer PNP1 may be formed to fill the first engraved pattern EP1. The first preliminary nanopost layer PNP1 may be formed on a top surface of the first peripheral material layer NNP1. For example, the first preliminary nanopost layer PNP1 may be formed to cover a top surface of the first peripheral material layer NNP1. The first preliminary nanopost layer PNP1 and the first peripheral material layer NNP1 may have different refractive index. The first preliminary nanopost layer PNP1 may include a material having a high refractive index. For example, the first preliminary nanopost layer PNP1 may include at least one of silicon (e.g., single-crystalline silicon (c-Si), polycrystalline silicon (p-Si), and amorphous silicon (a-Si)), groups 3-5 compound semiconductors (e.g., gallium arsenide (GaAs), gallium phosphide (GaP), and gallium nitride (GaN)), silicon carbide (SiC), titanium oxide (TiOₓ), or silicon nitride (SiNₓ). For example, depositing the first preliminary nanopost layer PNP1 may be performed using physical vapor deposition (PVD) process, chemical vapor deposition (CVD) process, and atomic layer deposition (ALD) process.

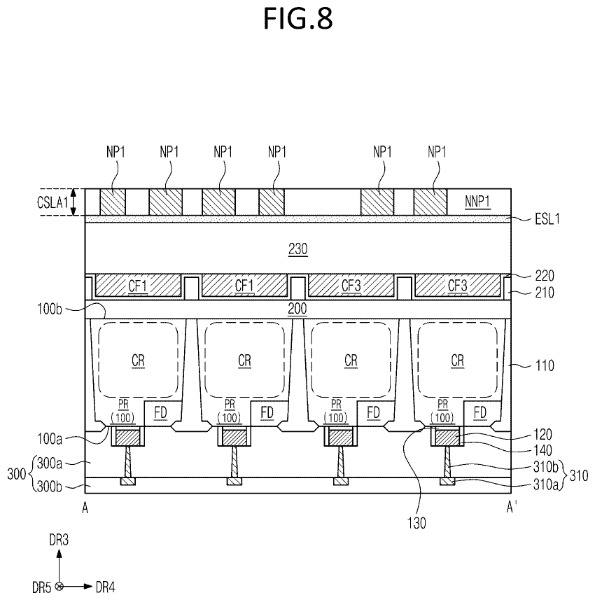

Referring to FIG. 8, according to an embodiment, the method may include forming first nanoposts NP1. For example, the first nanoposts NP1 may be formed by performing a planarization process on the first preliminary nanopost layer PNP1. For example, the planarization process may be performed using a chemical mechanical polishing (CMP) process. For example, the planarization process for the first preliminary nanopost layer PNP1 may be performed until the top surface of the first peripheral material layer NNP1 is exposed.

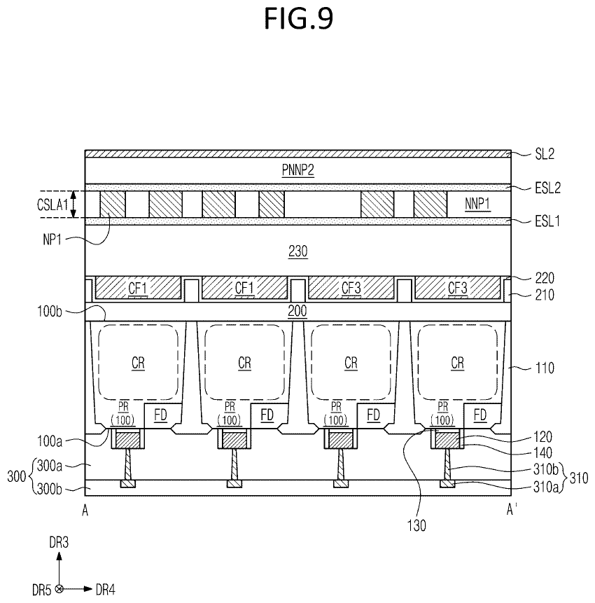

Referring to FIG. 9, according to an embodiment, the method may include forming a second etch stop layer ESL2 on a first color separation lens array CSLA1. The second etch stop layer ESL2 may be formed along the direction parallel to the first surface 100a. The second etch stop layer ESL2 may be configured to prevent the first color separation lens array CSLA1 from being damaged when the second preliminary peripheral material layer PNNP2, which will be described later, is etched. The second etch stop layer ESL2 may not be etched with a material used to etch the second preliminary peripheral material layer PNNP2. For example, the second etch stop layer ESL2 may include at least one of silicon oxide (SiOₓ), aluminum oxide (AlOₓ), hafnium oxide (HfOₓ), titanium oxide (TiOₓ), zirconium oxide (ZrOₓ), silicon nitride (SiNₓ), and silicon nitride (SiOₓN_{y}). For example, depositing the second etch stop layer ESL2 may be performed using physical vapor deposition (PVD) process, chemical vapor deposition (CVD) process, and atomic layer deposition (ALD) process.

According to an embodiment, the method may include forming a second preliminary peripheral material layer PNNP2 on the second etch stop layer ESL2. The second preliminary peripheral material layer PNNP2 may be formed along the direction parallel to the first surface 100a. The second preliminary peripheral material layer PNNP2 and a second preliminary nanopost layer PNP2, which will be described later, may have different refractive index. The second preliminary peripheral material layer PNNP2 may include a material having a low refractive index. For example, the second preliminary peripheral material layer PNNP2 may include an electrically insulating material (e.g., at least one of silicon oxide (SiOₓ), a photocurable resin (e.g., photoresist or polymethyl methacrylate (PMMA))). For example, depositing the second preliminary peripheral material layer PNNP2 may include physical vapor deposition (PVD) process, chemical vapor deposition (CVD) process, and atomic layer deposition (ALD) process can be performed using the process.

According to an embodiment, the method may include forming a second sacrificial layer SL2 on the second preliminary peripheral material layer PNNP2. The second sacrificial layer SL2 may be formed along the direction parallel to the first surface 100a. The second sacrificial layer SL2 may include an organic material. For example, the second sacrificial layer SL2 may include photoresist. The second sacrificial layer SL2 may be formed through a coating process. For example, the coating process may include spin-coating method, spray-coating method, dip-coating method, inkjet printing method, or slot-die coating method.

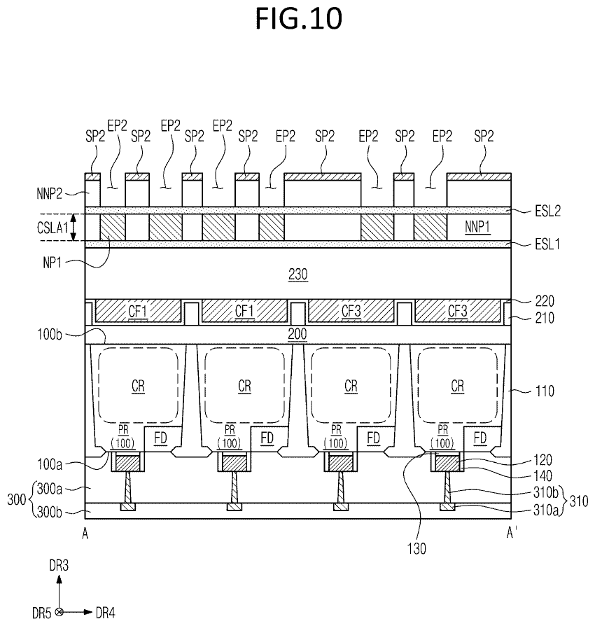

Referring to FIG. 10, according to an embodiment, the method may include forming second sacrificial patterns SP2. For example, the second sacrificial layer SL2 may be patterned to form second sacrificial patterns SP2. Forming the second sacrificial patterns SP2 may include an exposure process of irradiating light to a required region of the second sacrificial layer SL2 and a development process of removing either an exposed portion or a non-exposed portion. The second sacrificial patterns SP2 may be spaced apart from each other. The second preliminary peripheral material layer PNNP2 may be exposed between the second sacrificial patterns SP2.

According to an embodiment, the method may include forming second engraved patterns EP2. For example, the second preliminary peripheral material layer PNNP2 may be etched to form second engraved patterns EP2. Forming the second engraved patterns EP2 may include an etching process using the second sacrificial patterns SP2 provided on the second preliminary peripheral material layer PNNP2. Forming the second engraved patterns EP2 may be performed until the second etch stop layer ESL2 is exposed. When forming the second engraved patterns EP2, the second preliminary peripheral material layer PNNP2 may be formed as a second peripheral material layer NNP2. The second sacrificial patterns SP2 may be removed during the etching process or after the etching process is completed. For example, the etching process may be performed using a dry etching process or a wet etching process.

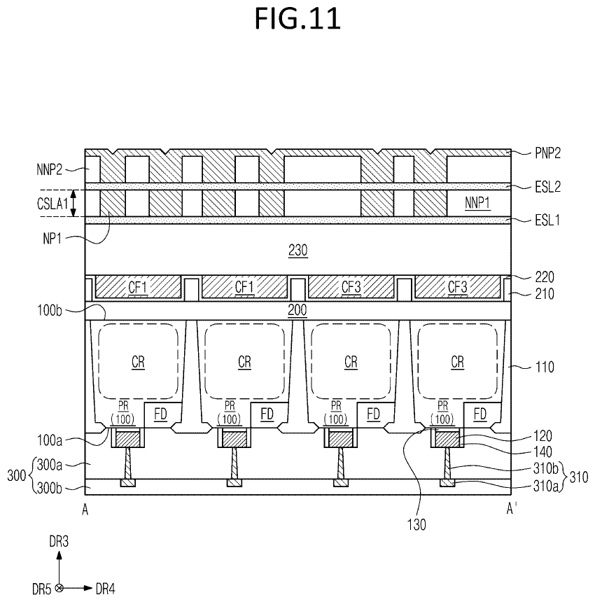

Referring to FIG. 11, according to an embodiment, the method may include forming the second preliminary nanopost layer PNP2 by filing the second engraved pattern EP2. The second preliminary nanopost layer PNP2 may be formed on a top surface of the second peripheral material layer NNP2. For example, the second preliminary nanopost layer PNP2 may be formed to cover a top surface of the second peripheral material layer NNP2. The second preliminary nanopost layer PNP2 and the second peripheral material layer NNP2 may have different refractive index. The second preliminary nanopost layer PNP2 may include a material having a high refractive index. For example, the second preliminary nanopost layer PNP2 may include silicon (e.g., single-crystalline silicon (c-Si), polycrystalline silicon (p-Si), and amorphous silicon (a-Si)), groups 3-5 compound semiconductors (e.g., gallium arsenide (GaAs), gallium phosphide (GaP), and gallium nitride (GaN)), silicon carbide (SiC), titanium oxide (TiO₂), or silicon nitride (SiNₓ). For example, depositing the second preliminary nanopost layer PNP2 may be performed using physical vapor deposition (PVD) process, chemical vapor deposition (CVD) process, and atomic layer deposition (ALD) process.

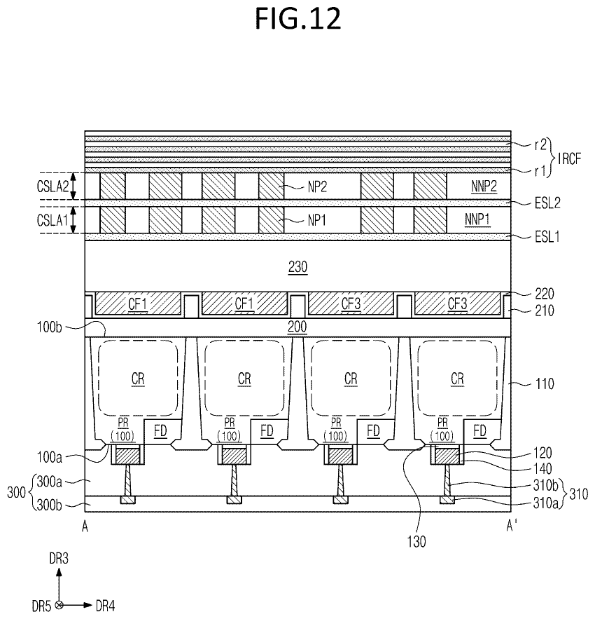

Referring to FIG. 12, according to an embodiment, the method may include forming second nanoposts NP2. The second nanoposts NP2 may be formed by performing a planarization process on the second preliminary nanopost layer PNP2. For example, the planarization process may be performed using a chemical mechanical polishing (CMP) process. For example, the planarization process for the second preliminary nanopost layer PNP2 may be performed until the top surface of the second peripheral material layer NNP2 is exposed.

According to an embodiment, the method may include forming an infrared cut-off filter IRCF on a second color separation lens array CSLA2. The infrared cut-off filter IRCF may be formed so that a first refractive layer r1 and a second refractive layer r2 intersect each other. The refractive index of the first refractive layer r1 may be smaller than the refractive index of the second refractive layer r2. For example, the first refractive layer r1 may include silicon oxide (SiOₓ). For example, the second refractive layer r2 may include titanium oxide (TiOₓ) or tantalum oxide (TaOₓ).

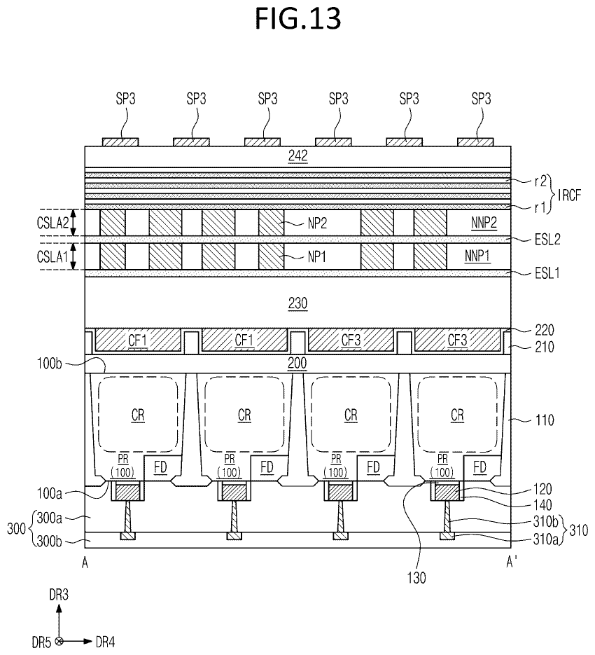

Referring to FIG. 13, according to an embodiment, the method may include forming a preliminary anti-reflective layer 242 on the infrared cutoff filter IRCF. The preliminary anti-reflective layer 242 may be configured along the direction parallel to the first surface 100a. For example, the preliminary anti-reflective layer 242 may include silicon oxide (SiOₓ), silicon nitride (SiNₓ), or a combination thereof. For example, depositing the preliminary anti-reflective layer 242 may be performed using physical vapor deposition (PVD) process, chemical vapor deposition (CVD) process, and atomic layer deposition (ALD) process.

According to an embodiment, the method may include forming a third sacrificial layer on the preliminary anti-reflective layer 242. The third sacrificial layer may be formed along the direction parallel to the first surface 100a. The third sacrificial layer may include an organic material. For example, the third sacrificial layer may include photoresist. The third sacrificial layer may be formed through a coating process. For example, the coating process may include spin-coating method, spray-coating method, dip-coating method, inkjet printing method, or slot die coating method.

The third sacrificial layer may be patterned to form third sacrificial patterns SP3. Forming the third sacrificial patterns SP3 may include an exposure process of irradiating light to a required region of the third sacrificial layer and a development process of removing either an exposed portion or a non-exposed portion. The third sacrificial patterns SP3 may be spaced apart from each other. The preliminary anti-reflective layer 242 may be exposed between the third sacrificial patterns SP3.

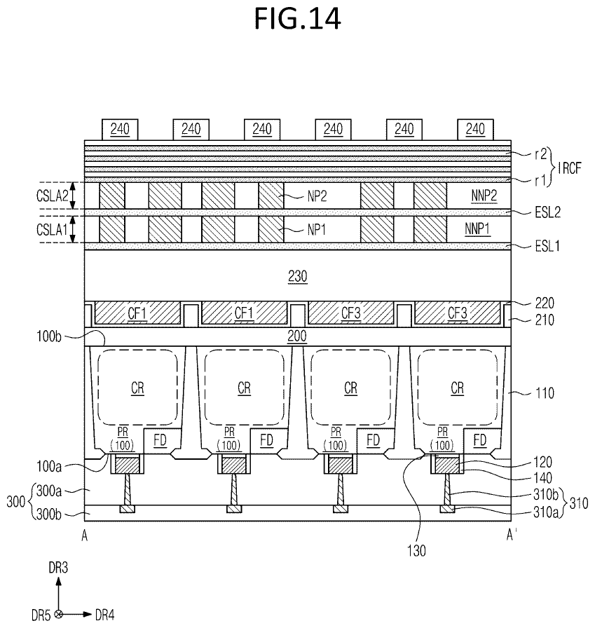

Referring to FIG. 14, according to an embodiment, the method may include forming anti-reflective patterns 240. For example, the preliminary anti-reflective layer 242 may be etched to form anti-reflective patterns 240. Forming the anti-reflective patterns 240 may include an etching process using the third sacrificial patterns SP3 provided on the preliminary anti-reflective layer 242. The third sacrificial patterns SP3 may be removed during or after the etching process. For example, the etching process may be performed using a dry etching process or a wet etching process. The anti-reflective patterns 240 may be spaced apart from each other. The infrared cut-off filter IRCF may be exposed between the anti-reflective patterns 240.

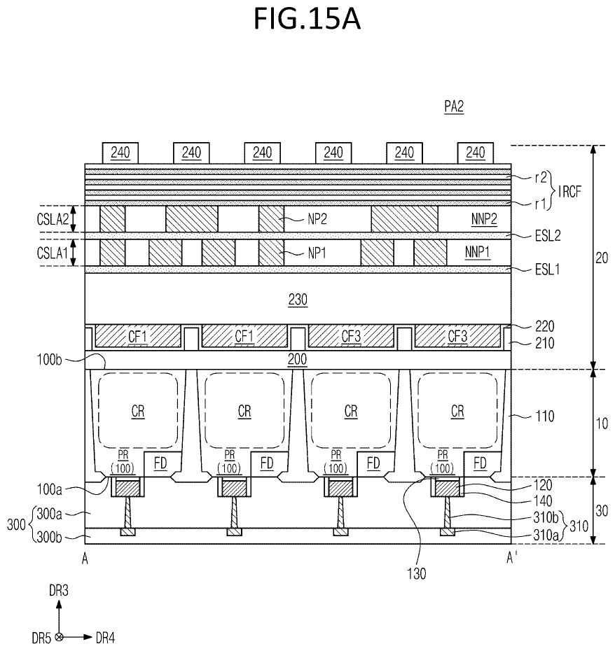

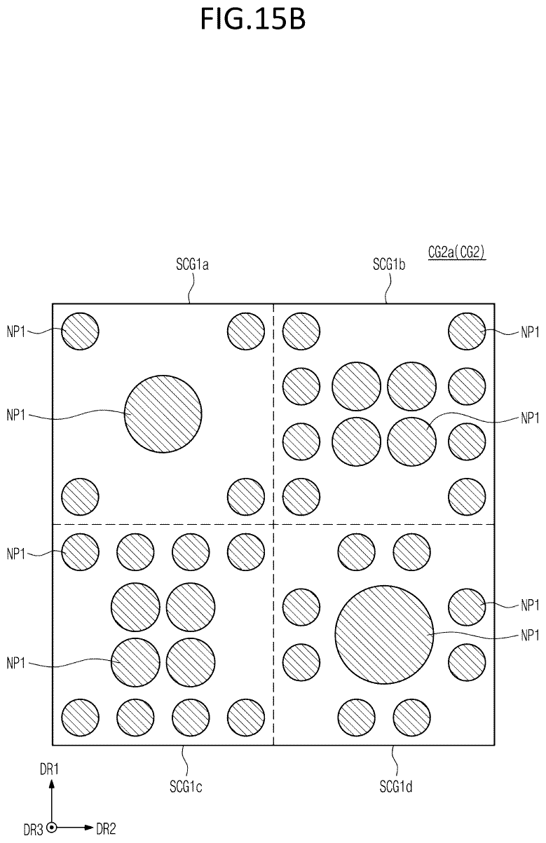

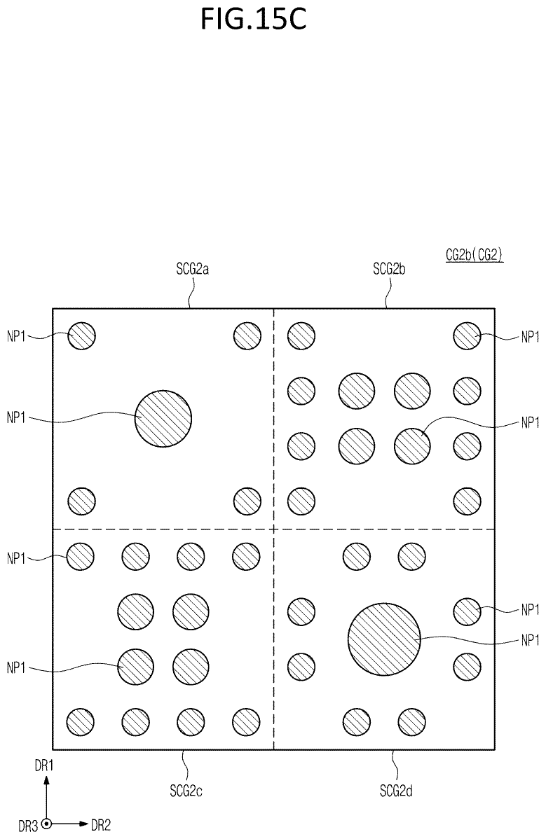

FIG. 15A is a cross-sectional view illustrating an image sensor according to one or more example embodiments. FIGS. 15B and 15C are plan views for explaining the image sensor of FIG. 15A. For brevity of explanation, content substantially the same as that described with reference to FIGS. 4A to 4I may not be described.

Referring to FIGS. 15A to 15C, an image sensor PA2 may be provided. Unlike the description with reference to FIGS. 4A to 4I, the first and second color separation lens arrays CSLA1 and CSLA2 may be different from each other. In one or more example embodiments, the first nanoposts NP1 of the first color separation group CG1 and the second nanoposts NP2 of the second color separation group CG2 may be arranged in different patterns. From a plan view, at least some of the first nanoposts NP1 may be spaced apart from the second nanoposts NP2. In one or more example embodiments, the number or the shape of the first nanoposts NP1 of the first color separation groups CG1 and the second nanoposts NP2 of the second color separation group CG2 may be different from each other.

The first nanoposts NP1 in the first color separation group CG1, which is provided relatively far from the center of the first color separation lens array CSLA1, may have a smaller width than that of the first nanoposts NP1 provided relatively closer to the center of the first color separation lens array CSLA1. For example, as the chief ray angle of the incident light incident on the first color separation groups CG1 is increased by 1 degree, the width of the first nanoposts NP1 may be decreased by 0.227 percent (%).

The first nanoposts NP2 in the first color separation group CG2, which is provided relatively far from the center of the first color separation lens array CSLA2, may have a smaller width than that of the first nanoposts NP2 provided relatively closer to the center of the first color separation lens array CSLA2. For example, as the chief ray angle of the incident light incident on the second color separation groups CG2 is increased by 1 degree, the width of the second nanoposts NP2 may be decreased by 0.227 percent (%).

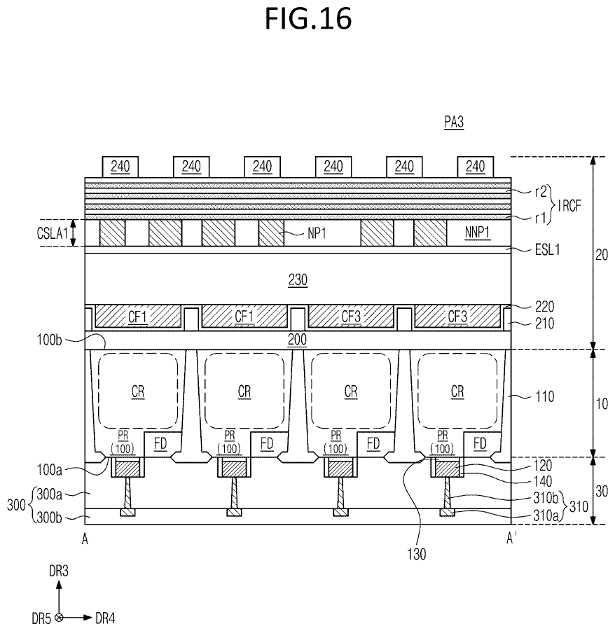

FIG. 16 is a cross-sectional view illustrating an image sensor according to one or more example embodiments. For brevity of explanation, content substantially the same as that described with reference to FIGS. 4A to 4I may not be described.

Referring to FIG. 16, an image sensor PA3 may be provided. Unlike the description with reference to FIGS. 4A to 4I, the optical element layer 20 may include the first color separation lens array CSLA1. The first color separation lens array CSLA1 may be configured to separate the incident light IL passing through the first color separation lens array CSLA1 into the first wavelength light, the second wavelength light, and the third wavelength light. For example, the first color separation lens array CSLA1 may be configured to focus the first wavelength light into the first sub-pixel group SPX1. For example, the first color separation lens array CSLA1 may be configured to focus the second wavelength light into the second and third sub-pixel groups SPX2 and SPX3. For example, the first color separation lens array CSLA1 may be configured to focus the third wavelength light into the fourth sub-pixel group SPX4. For example, the focusing characteristics of the first color separation lens array CSLA1 for the first wavelength light, the second wavelength light, and the third wavelength light may be determined by the first nanoposts NP1 included in the first color separation lens array CSLA1.

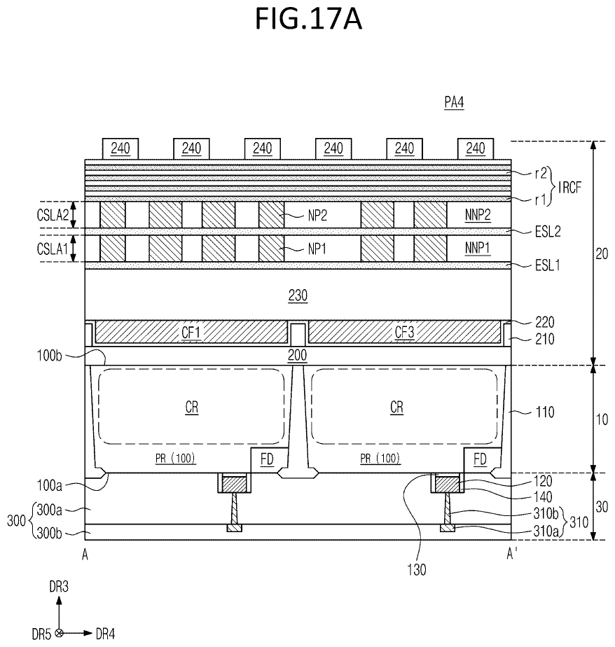

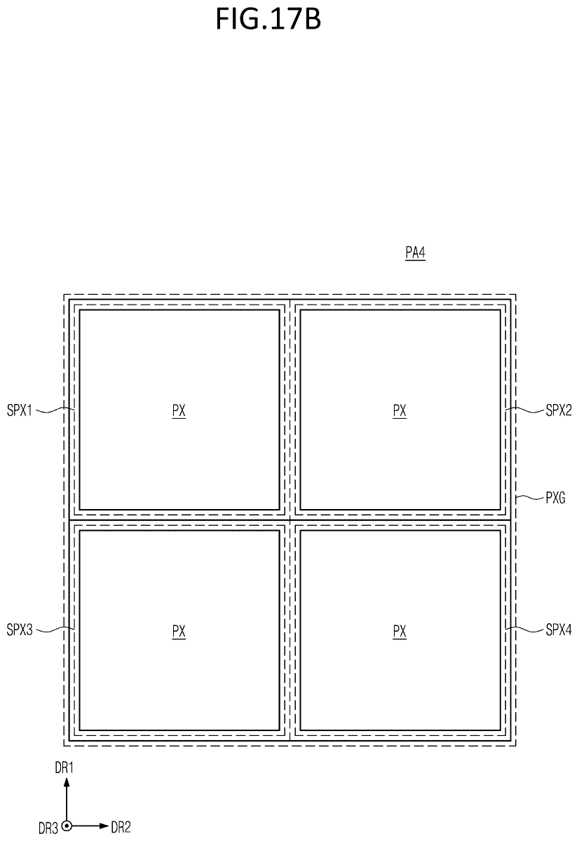

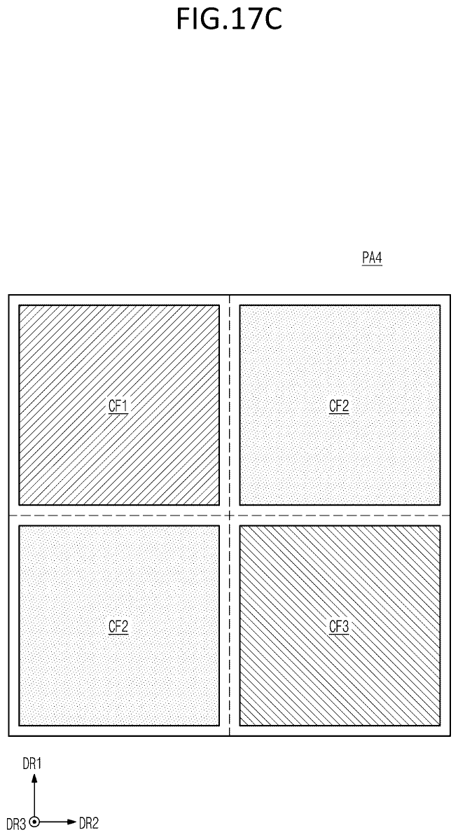

FIG. 17A is a cross-sectional view illustrating an image sensor according to one or more example embodiments. FIGS. 17B and 17C are plan views for explaining the image sensor of FIG. 17A. For brevity of explanation, content substantially the same as that described with reference to FIGS. 4A to 4I may not be described.

Referring to FIGS. 17A to 17C, an image sensor PA4 may be provided. Unlike the description with reference to FIGS. 4A to 4I, each of the first to fourth sub-pixel groups SPX1 to SPX4 may include one pixel PX. The first color filter CF1 may be provided on the pixel PX of the first sub-pixel group SPX1. The second color filter CF2 may be provided on the pixel PX of the second sub-pixel group SPX2. The second color filter CF2 may be provided on the pixel PX of the third sub-pixel group SPX3. The third color filter CF3 may be provided on the pixel PX of the fourth sub-pixel group SPX4.

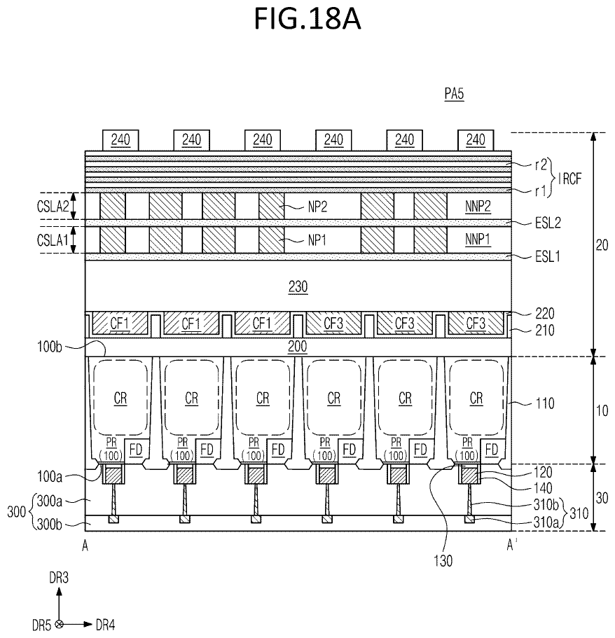

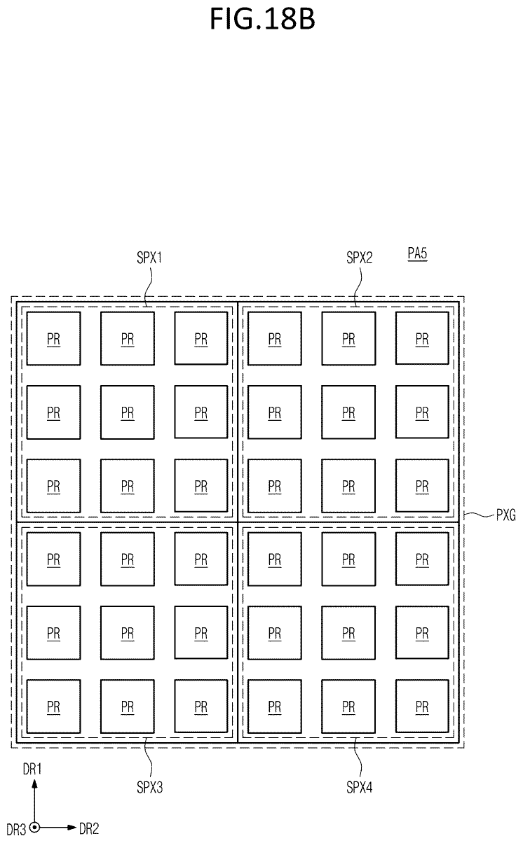

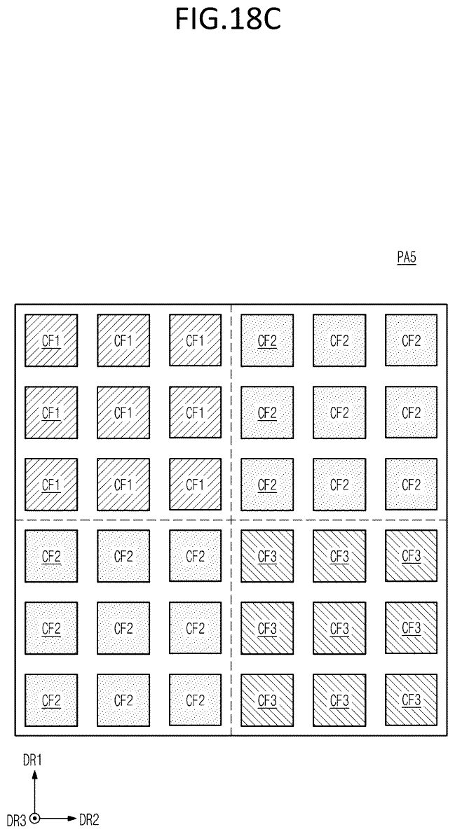

FIG. 18A is a cross-sectional view illustrating an image sensor according to one or more example embodiments. FIGS. 18B and 18C are plan views for explaining the image sensor of FIG. 18A. For brevity of explanation, content substantially the same as that described with reference to FIGS. 4A to 4I may not be described.

Referring to FIGS. 18A to 18C, an image sensor PA5 may be provided. Unlike the description with reference to FIGS. 4A to 4I, each of the first to fourth sub-pixel groups SPX1 to SPX4 may include nine pixels PX. For example, the pixel regions PR may be provided in the form of a 3×3 array.

First color filters CF1 arranged in the 3×3 array may be provided on each pixel PX of the first sub-pixel group SPX1. Second color filters CF2 arranged in the 3×3 array may be provided on each of the pixels PX of the second sub-pixel group SPX2. The second color filters CF2 arranged in the 3×3 array may be provided on each of the pixels PX of the third sub-pixel group SPX3. Third color filters CF3 arranged in the 3×3 array may be provided on each of the pixels PX of the fourth sub-pixel groups SPX4.

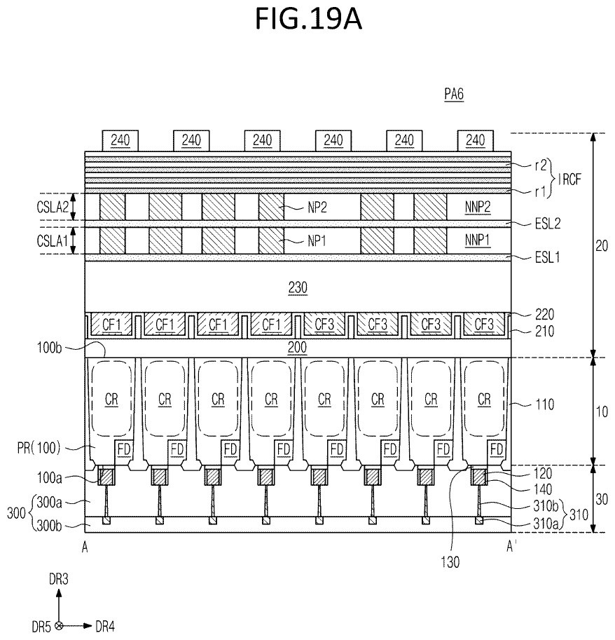

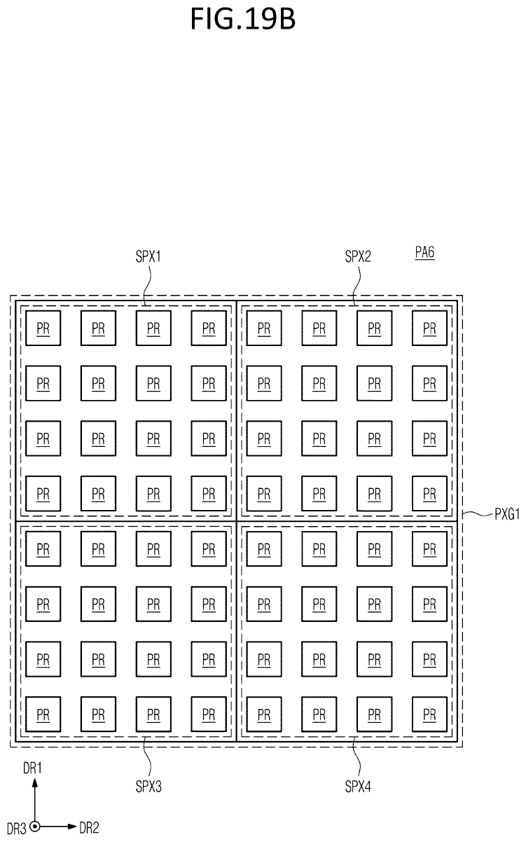

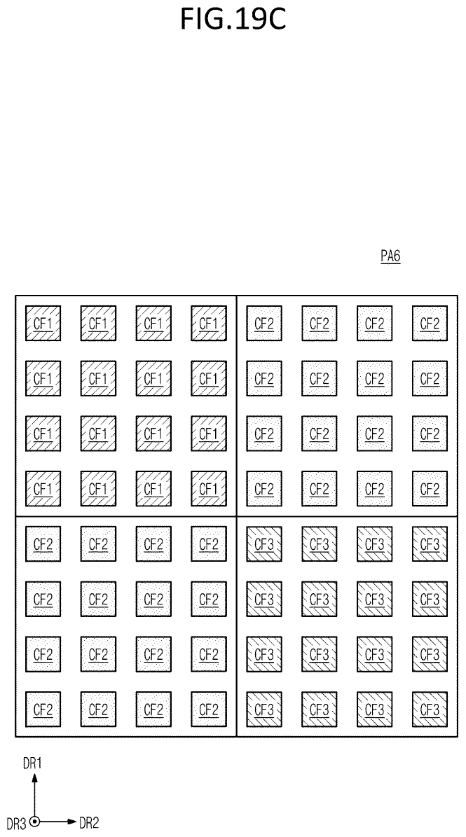

FIG. 19A is a cross-sectional view illustrating an image sensor according to one or more example embodiments. FIGS. 19B and 19C are plan views for explaining the image sensor of FIG. 19A. For brevity of explanation, content substantially the same as that described with reference to FIGS. 4A to 4I may not be described.

Referring to FIGS. 19A to 19C, an image sensor PA6 may be provided. Unlike the description with reference to FIGS. 4A to 4I, each of the first to fourth sub-pixel groups SPX1 to SPX4 may include 16 pixels PX. For example, pixels PX may be provided in the form of a 4×4 array.

First color filters CF1 arranged in the 4×4 array may be provided on each of the pixels PX of the first sub-pixel group SPX1. Second color filters CF2 arranged in the 4×4 array may be provided on each of the pixels PX of the second sub-pixel group SPX2. The second color filters CF2 arranged in the 4×4 array may be provided on each of the pixels PX of the third sub-pixel group SPX3. Third color filters CF3 arranged in the 4×4 array may be provided on each of the pixels PX of the fourth sub-pixel group SPX4.

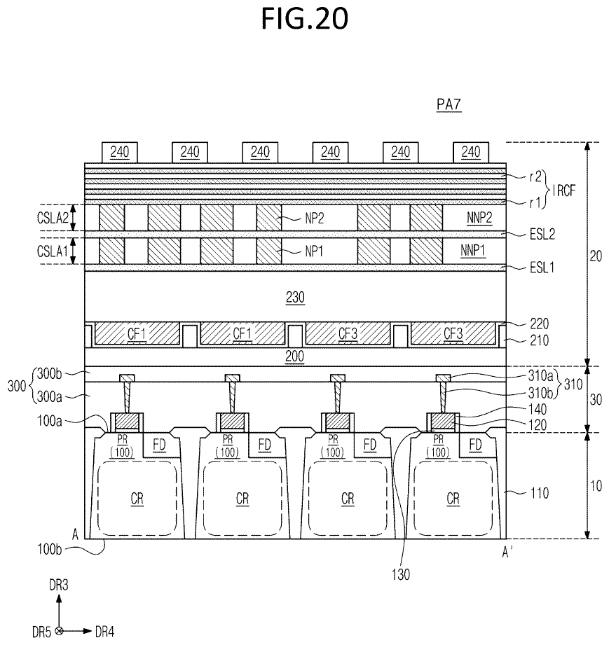

FIG. 20 is a cross-sectional view illustrating an image sensor according to one or more example embodiments. For brevity of explanation, content substantially the same as that described with reference to FIGS. 4A to 4I may not be described.

Referring to FIG. 20, an image sensor PA7 may be provided. The image sensor PA7 may include a device layer 10, an optical element layer 20, and a wiring layer 30. Unlike the description with reference to FIGS. 4A to 4F, the wiring layer 30 may be provided between the device layer 10 and the optical element layer 20. The wiring layer 30 and the optical element layer 20 may be provided on the substrate region 100. For example, the wiring layer 30 and the optical element layer 20 may be sequentially provided on the first surface 100a of the substrate region 100. For example, the image sensor PA7 may be operated in a front side illumination (FSI) mode.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

The above description of one or more example embodiments of the inventive concepts provides examples for explanation of the technical idea of the disclosure. Therefore, the inventive concepts are not limited to the above one or more example embodiments. Within the technical idea of the disclosure, various modifications and changes are possible, such as combining and implementing the above one or more example embodiments by those skilled in the art.

What is claimed is:

1. An image sensor comprising:
a pixel layer including a plurality of pixels; and
a first color separation lens array provided on the pixel layer, the first color separation lens array comprising a plurality of first color separation groups,
wherein the plurality of first color separation groups comprise:
a first first color separation group adjacent to a center of the first color separation lens array, and
a second first color separation group adjacent to an edge of the first color separation lens array,
wherein the first first color separation group comprises one or more first nanoposts and the second first color separation group comprises one or more second nanoposts, and
wherein a width of the one or more first nanoposts is greater than a width of the one or more second nanoposts.

2. The image sensor of claim 1, wherein a difference between the width of the one or more first nanoposts and the width of the one or more second nanoposts is based on a chief ray angle of first incident light incident on the first first color separation group and a chief ray angle of second incident light incident on the second first color separation group.

3. The image sensor of claim 1, wherein the one or more first nanoposts comprise a plurality of first nanoposts,
wherein the one or more second nanoposts comprise a plurality of second nanoposts,
wherein the plurality of first nanoposts and the plurality of second nanoposts are arranged in a substantially same pattern.

4. The image sensor of claim 1, further comprising:
a second color separation lens array provided on the first color separation lens array, the second color separation lens array comprising a plurality of second color separation groups,
wherein the plurality of second color separation groups comprise:
a first second color separation group adjacent to a center of the second color separation lens array and provided on the first first color separation group; and
a second second color separation group adjacent to an edge of the second color separation lens array and provided on the second first color separation group,
wherein the first second color separation group comprises one or more third nanoposts and the second second color separation group comprises one or more fourth nanoposts, and
wherein a width of the one or more third nanoposts is greater than a width of the one or more fourth nanoposts.

5. The image sensor of claim 4, wherein the first second color separation group and the second second color separation group overlap with the first first color separation group and the second first color separation group, respectively, along a stacking direction of the first color separation lens array and the second color separation lens array.

6. The image sensor of claim 4, in a view in a stacking direction of the first color separation lens array and the second color separation lens array, the first second color separation group and the second second color separation group are arranged to be offset from the first first color separation group and the second first color separation group, respectively.

7. The image sensor of claim 4, wherein the one or more third nanoposts comprise a plurality of third nanoposts,
wherein the one or more fourth nanoposts comprise a plurality of fourth nanoposts,
wherein the plurality of third nanoposts and the plurality of fourth nanoposts are arranged in a substantially same pattern.

8. The image sensor of claim 4, wherein the one or more first nanoposts comprise a plurality of first nanoposts,
wherein the one or more third nanoposts comprise a plurality of third nanoposts,
wherein the plurality of first nanoposts and the plurality of the third nanoposts are arranged in a substantially same pattern.

9. The image sensor of claim 4, wherein the one or more first nanoposts comprise a plurality of first nanoposts,
wherein the one or more third nanoposts comprise a plurality of third nanoposts,
wherein the plurality of first nanoposts are arranged in a different pattern than the plurality of the third nanoposts.

10. The image sensor of claim 1, wherein, based on a difference between a chief ray angle of the first incident light incident on the first first color separation group and a chief ray angle of the second incident light incident on the second first color separation group being 1 degree, the width of the one or more second nanoposts is 0.227% smaller than the width of the one or more first nanoposts.

11. The image sensor of claim 1, wherein the pixel layer further comprises a plurality of sub-pixel groups corresponding to one of the plurality of the first color separation groups,
wherein each of the plurality of sub-pixel groups comprises one or more pixels of the plurality of pixels,
wherein the one of the plurality of first color separation groups distributes incident light to the plurality of sub-pixel groups based on a wavelength.

12. The image sensor of claim 11, wherein each of the plurality of sub-pixel groups comprises one pixel, 4 pixels arranged in a 2×2 array, 9 pixels arranged in a 3×3 array, 16 pixels arranged in a 4×4 array.

13. The image sensor of claim 11, further comprising:
a plurality of color filters provided between the first color separation lens array and the pixel layer,
wherein the plurality of color filters are provided on one or more pixels in each of the plurality of sub-pixel groups.

14. The image sensor of claim 1, further comprising:
an infrared cut-off filter provided on the first color separation lens array.

15. A method for manufacturing an image sensor comprising:
forming a pixel layer including a plurality of pixels; and
forming a first color separation lens array on the pixel layer, the pixel layer including a plurality of first color separation groups,
wherein the plurality of first color separation groups comprise:
a first first color separation group adjacent to a center of the first color separation lens array, and
a second first color separation group adjacent to an edge of the first color separation lens array,
wherein the first first color separation group comprises one or more first nanoposts and the second first color separation group comprises one or more second nanoposts, and
wherein a width of the one or more first nanoposts is greater than a width of the one or more second nanoposts.

16. The method for manufacturing the image sensor of claim 15, wherein the forming the first color separation lens array comprises:
forming a first etch stop layer on the pixel layer;
forming a first preliminary peripheral material layer on the first etch stop layer;
forming a first sacrificial layer on the first preliminary peripheral material layer;
forming first sacrificial patterns and a first peripheral material layer by performing an etch-back process on the first sacrificial layer;
forming a first preliminary nanopost layer on the first peripheral material layer; and
forming first nanoposts by performing a planarization process on the first preliminary nanopost layer.

17. The method for manufacturing the image sensor of claim 15, further comprising:
forming a second color separation lens array on the first color separation lens array,
wherein the forming the second color separation lens array comprises:
forming a second etch stop layer on the first color separation lens array;
forming a second preliminary peripheral material layer on the second etch stop layer;
forming a second sacrificial layer on the second preliminary peripheral material layer;
performing an etch-back process on the second sacrificial layer to form second sacrificial patterns and a second peripheral material layer;
forming a second preliminary nanopost layer on the second peripheral material layer; and
forming second nanoposts by performing a planarization process on the second preliminary nanopost layer.

18. An image sensor comprising:
a pixel layer;
a wiring layer electrically connected to the pixel layer; and
an optical element layer configured to focus incident light onto the pixel layer,
wherein the optical element layer comprises a first color separation lens array comprising a plurality of first color separation groups,
wherein the plurality of first color separation groups comprise:
a first first color separation group adjacent to a center of the first color separation lens array, and
a second first color separation group adjacent to an edge of the first color separation lens array,
wherein the first first color separation group comprises one or more first nanoposts and the second first color separation group comprises one or more second nanoposts, and
wherein a width of the one or more first nanoposts is greater than a width of the one or more second nanoposts.

19. The image sensor of claim 18, wherein the wiring layer and the optical element layer are spaced apart from each other, and
wherein the pixel layer is provided between the wiring layer and the optical element layer.

20. The image sensor of claim 18, wherein the pixel layer and the optical element layer are spaced apart from each other, and
wherein the wiring layer is provided between the pixel layer and the optical element layer.
